(19) United States
(12) Patent Application Publication
(10) Pub. No.: US 2025/0154031 A1
(43) Pub. Date: May 15, 2025

(54) Systems and Methods for Water Purification

(71) Applicant: BOARD OF REGENTS, THE UNIVERSITY OF TEXAS SYSTEM, Austin, TX (US)

(72) Inventors: Donglei FAN, Austin, TX (US); Xianfu LUO, Austin, TX (US); Weigu LI, Austin, TX (US); Yifei LIU, Austin, TX (US); Huifeng LI, Austin, TX (US)

(21) Appl. No.: 18/947,985

(22) Filed: Nov. 14, 2024

Related U.S. Application Data
(60) Provisional application No. 63/548,533, filed on Nov. 14, 2023.

(51) Int. Cl. C02F 1/48; C23C 16/01; C23C 16/26; C25D 5/00; C25D 5/04; C25D 5/50

(52) U.S. Cl. CPC C02F 1/48; C23C 16/01; C23C 16/26; C25D 5/04; C25D 5/50; C25D 5/623; C02F 2201/48; C02F 2303/04

(57) ABSTRACT

Disclosed are methods and systems for water purification.

### CROSS-REFERENCE TO RELATED APPLICATIONS

This application claims benefit of priority of U.S. Provisional Application No. 63/548,533, filed Nov. 14, 2023, which is hereby incorporated herein by reference in its entirety.

### STATEMENT REGARDING FEDERALLY SPONSORED RESEARCH OR DEVELOPMENT

This invention was made with government support under Grant no. CMMI1563382 awarded by the National Science Foundation. The government has certain rights in the invention.

### BACKGROUND

Fresh water in lakes, rivers, ponds, and streams has sustained the development of human societies for millions of years. However, most fresh water in nature does not meet today's drinkable standard set by the World Health Organization, particularly, due to the presence of various disease-causing pathogens. The inadequate access to clean water has become an inflicting issue, not only in rural and developing areas, but also in modern cities. The challenge is further compounded by the evidenced increase in frequencies and magnitude of extreme weather due to climate change. For instance, the winter storm in Texas in 2021 caused half of the state's population losing access to drinking water for days or weeks. The safety and sustainable development of society demand innovative technologies for water treatment in a robust, energy-efficient, cost-effective, and point-of-use (POU) manner.

A variety of water treatment techniques have been developed for large-scale water processing, such as reverse osmosis (RO), thermal distillation-based multi-stage flash and multi-effect distillation, and electrodialysis that demand infrastructures and resources. Among these technologies, RO is often seen in home-based POU water treatment, however, it requires high water pressure and is susceptible to membrane fouling. Recently, solar steaming (SS) with simple device designs becomes promising for POU renewable water purification; its performance depends on weather conditions and geographic locations, which is less accountable in challenging times, such as during extreme weather conditions. Also, intrinsically, solar steaming is a high energy-consuming technology, the working principle of which requires a large latent heat for the liquid-to-vapor phase transition. Chemical disinfection is simple and convenient; nonetheless, it uses strong oxidative agents, such as ozone, chlorine, and chlorine dioxide, which are hazardous to handle and could generate carcinogenic byproducts bringing dangers to people's health.

Electrochemical-mediated inactivation (EMI) has been explored for water treatment, which exhibits advantages owing to its facile scheme in lysing bacterial cells, removing heavy metals and organic contaminants, and self-cleaning. When utilized for water disinfection, EMI operates mainly via mechanisms of electroporation and electrochemical oxidation; the former requires the application of a high-intensity DC field (e.g., at 10⁷ V·m⁻¹) for damaging bacterial cells' membranes. The latter requires electrochemically-created species in an ionic solution for water disinfection. For instance, sulfate (Na₂SO₄) (50 mM sodium, 8.1 mS/cm) is used for improved electric conductivity supporting the electrochemical reactions. Efforts have been made to modify electrodes with nanowires to amplify the localized electric field with the “lightning rod” effect so that it is possible to lyse bacteria with electroporation at a reduced DC voltage, e.g., <20 V Silver, Cu₃P, and CuO nanowires have been synthesized on conducting surfaces for this purpose. The application of a DC voltage, e.g., at only 1 V, can lyse cells, which, however, dissolves the nanowires and introduces metal ions to water. In the demonstrations, the bacteria are mostly transported to the electrodes via forced flows with water pumping or stirring, which enables high speed water process at the cost of POU complexity.

Notably, the recent advances in micro/nanomachines powered by external stimuli, including light, magnetic fields, and chemical fuels have been applied in water treatment, including decontaminating bacteria. The designed structures and actuation mechanisms of micro/nanomachines demonstrate enhanced efficiency in interacting with substances in water compared to their static counterparts. Although such an approach is still largely at the proof-of-concept stage, e.g., treating water of a milliliter confined in a microwell, it inspires a different way of water purification.

### SUMMARY

Herein, we report a meritorious working principle, and the associated device scheme and materials for water purification, including water disinfection, the removal of chemical contaminants (e.g., mercury, lead, PFAS, etc.) from water, or a combination thereof. The devices and methods described herein facilitate the physical removal of bacteria in contrast to cell lysis employed in many studies. The concept is based on manipulating bacterial cells via exploring the interaction between bacterial cells and high-frequency AC electric fields, created from strategically designed large-scale 3D porous dendritic graphite foam (PDGF). The bacteria can be mechanically aligned, transported, captured, and removed from bulk still water for water treatment. In examples described herein, a working scheme demonstrates a successful removal of 99.997% Escherichia coli (E. coli) cells in 25 min with an energy consumption of only 435.5 J·L⁻¹, among the lowest of various water-disinfection technologies. The example device is robust that shows no observable functional degradation after 20 repeated applications, and can practically purify natural water from Waller Creek at UT Austin. Brownian dynamics simulation is carried out to shed light on the bacterial removal mechanism. The operation of the device does not require forced flows and is low-cost, durable, and scalable for portable water.

Additional advantages will be set forth in part in the description that follows, and in part will be obvious from the description, or may be learned by practice of the aspects described below. The advantages described below will be realized and attained by means of the elements and combinations particularly pointed out in the appended claims. It is to be understood that both the foregoing general description and the following detailed description are exemplary and explanatory only and are not restrictive.

### DESCRIPTION OF DRAWINGS

FIGS. 1A-1E. (1A) Schematic of the fabrication process of dendritic graphite foams. Ni/Cu dendrites (II) are directly deposited on commercial Ni foams (I) via electroplating, followed by annealing at 1000° C. to strengthen the attachment strength between the dendrites and the Ni substrates (III). Thin graphite is grown on the dendritic Ni foam to replicate the branched morphology of the metallic foam (IV). Freestanding graphite foam (V) with replicated branched microstructures is finally obtained after chemical etching the Ni substrates. SEM images of (1B) commercial Ni foams, (1C) dendritic Ni foams, and (1D) free-standing dendritic graphite foams. (1E) Photographs of (I) commercial Ni foam, (II) Ni/Cu dendrites@Ni foam (before annealing), (III) Dendritic Ni foam (DNF, after annealing), (IV) graphite@dendritic Ni foam (GDNF, before etching), (V) free-standing dendritic graphite foam (DGF, after metal etching).

FIGS. 2A-2I. Characterization of the dendritic foams. SEM images of (2A) low-density-short-branched dendritic foam (LSDF) [inset: non-dendritic graphite foam (NDGF)], and the corresponding (2B) low-density-short-branched dendritic graphite foam (LSDGF), (2C) low-density-long-branched dendritic foam (LLDF) and the corresponding (2D) low-density-long-branched dendritic graphite foam (LLDGF), (2E) high-density-long-branched dendritic foam (HLDF, or dendritic Ni Foam, DNF) and the corresponding (2F) high-density-long-branched dendritic graphite foam (LLDGF). Overall, the branched morphologies of DNFs are well preserved in the DGFs. (2G) TEM image of DGFs. (2H) Comparison of BET surface area test results of dendritic foams with different morphologies. NF: Ni foam; LSDF: low-density-short-branched dendritic foam; LLDF: low-density-long-branched dendritic foam; HLDF: high-density-long-branched dendritic foam. (2I) Raman spectrum of DGFs.

FIGS. 3A-3D. (3A) Removal performance of E. coli cells increases as AC peak-to-peak voltage (10 MHz) increases; (3B) Increases of the release bacteria with the off-time of electric field. Removal efficiency depends on (3C) frequency (frequency below 100 Hz will be discussed separately), and (3D) field application duration.

FIGS. 4A-4D. Removal efficiency of E. coli cells at 10 MHz, 8V, depends on (4A) morphology of DGFs electrodes (AG: planar Au-coated glass electrode for control experiment), (4B) assembling density of DGFs electrodes, (4C) volume of contaminated water, and (4D) distance between DGFs electrode pairs.

FIGS. 5A-5E. Brownian Dynamics simulation result of bacteria purification in the 250 μm gap microelectrodes. (5A) Capture efficiency versus time by diffusion, locomotion, DEP, and all three processes synergistically. (5B-5E) the untrapped bacteria distribution at different time stamps with (5B) all three processes activated, (5C) locomotion activated, (5D) DEP activated, and (5E) diffusion activated.

FIGS. 6A-6H. E. coli (6A) and shigella cells (6B) in pseudo-colors captured by a dendritic graphite foam. Scale bars in (6A) and (6B): 3 μm. (6C) Durability of the dendritic graphite foam in the efficient capture and removal of bacteria. Insert: Cross-section schematic of PDGF. (6D) Diagram of test circuit for energy consumption. R₂ represents a known resistance of 1.5 kΩ, R₁ and C₁ together represent our water disinfection device. (6E) Comparison of energy consumption of different bacterial disinfection approaches. (6F) 125-ml portable disinfection cup applied for the disinfection of natural water collected from the Waller creek at UT-Austin, (6G) cell culture results of water from the Waller creek before and after electric-field capture (EC), and (6H) tests of bacteria in water from the Waller creek before and after electric-field capture. In yellow: bacterial positive; in purple: bacterial negative.

FIG. 7. Schematic of concept and device design of the AC-electric-field-powered dendritic graphite foams (DGFs) electrodes for the removal of bacterial cells from contaminated bulk water. The bacterial cells are captured and enriched on the DGFs electrodes with an applied AC electric field, and then removed from the water samples. AC: AC voltage and G: ground.

FIGS. 8A-8D. Motions of cells under an AC electric field, (8A) No E-field, random movement, (8B) with E-field: 8 V, 10 MHz, aligned, (8C) application of an E-field for ˜2 min attracts most bacteria cells to the electrodes, (8D) E-field off: cells released.

FIGS. 9A-9D. SEM images of commercial Ni foams, indicating the porous and multi-layered structures

FIGS. 10A-10I. Supplementary SEM images of (10A-10C) dendritic Ni foams, (10D-10F) graphite@dendritic Ni foams, (10G-10I) dendritic graphite foams.

FIGS. 11A-11C. Elements and their distributions in the diverging microbranches of the DNFs, showing that the microbranches are constituted of Ni and Cu.

FIG. 12. Elements in the diverging microbranches of the dendritic Ni foams.

FIGS. 13A-13C. SEM images of the non-dendritic graphite foams directly fabricated from commercial Ni foams (NDGF).

FIGS. 14A-14C. (14A-14B) TEM images of the as-fabricated dendritic graphite foams, (14C) characterization of the crystal plane (1 1 1) of the graphite.

FIG. 15. Removal efficiency of bacterial cells at low AC frequencies (1-100 Hz).

FIG. 16. Electrochemical series of different metal elements.

FIGS. 17A-17B. Demonstration that metal dendrites dissolve in water under applied voltage, illustrating the importance of using graphite foams as electrodes in water purification systems. (17A) observation of color change of water; (17B) metal ions detected with commercial metal check kit.

FIG. 18. Conductive glass electrodes with Au coating (AG) for control experiments: 50 nm Au@5 nm Cr@10 nm SiO2@glass.

FIGS. 19A-19D. BET surface area test of (19A) Ni foam (NF), (19B) low-density-long-branched dendritic foams (LLDF), (19C) low-density-short-branched dendritic foam (LSDF), (19D) high-density-long-branched dendritic foam (HLDF).

FIGS. 20A-20D. Re-configurable DGFs electrodes in water containers with different distances between electrode pairs, i.e., (20A) 12.75 mm, (20B) 5.625 mm, (20C) 3.25 mm, (20D) 2.75 mm.

FIGS. 21A-21B. Removal performance of shigella cells by AC electric-field-powered DGFs electrodes depends on (21A) frequency of AC electric field (at 8 V), (21B) distance between DGFs electrode pairs (at 8 V and 1 kHz).

FIGS. 22A-22D. Velocity characterization of bacterial cells in microelectrodes. (22A) Velocity statistics of freely moving E. coli cells in DI water medium. (22B) Velocity distribution of freely moving E. coli cells in DI water medium fitted by Gaussian distribution given by

$$f ( x ) = \frac{1}{σ \sqrt{2 π}} {e}^{- \frac{1}{2} {( \frac{x - μ}{σ} )}^{2}} ,$$

where f(x) is the velocity distribution density function, x is velocity, σ=2.2 μm/s, and μ=5.1 μm/s. (22C) Velocity of E. coli cell (moving towards the electrode) at different positions of an annular electrode under an AC electric field (at 8 V and 10 MHz). (22D) Velocity of shigella cell (moving towards the electrode) at different positions of an annular electrode under an AC electric field (at 8 V and 10 MHz).

FIGS. 23A-23F. SEM images of bacterial cells captured on the DGFs electrodes, (23A-23C) E. coli and (23D-23F) shigella.

FIG. 24. SEM image of DGF electrode after 20-time water treatment applications.

FIG. 25. E. coli count in Waller creak at UT Austin

FIGS. 26A-26C. Portable bacteria disinfection cup, 125 mL in volume

FIG. 27. EDX spectra of PGDF electrode before and after applying an AC voltage of 10 MHz, 20 Vpp for 25 min in simulated river water. No signal other than Carbon can be detected.

FIG. 28. Flow cell with a glass-pot appearance to enable easy filling and pouring of water after treatment.

### DETAILED DESCRIPTION

### Definitions

Unless otherwise defined, all technical and scientific terms used herein have the same meaning as commonly understood by one of ordinary skill in the art to which this invention belongs. Methods and materials are described herein for use in the present invention; other, suitable methods and materials known in the art can also be used. The materials, methods, and examples are illustrative only and not intended to be limiting. All publications, patent applications, patents, sequences, database entries, and other references mentioned herein are incorporated by reference in their entirety. In case of conflict, the present specification, including definitions, will control.

### Porous Dendritic Graphite Foams and Methods of Making Thereof

Examples of porous dendritic graphite foams that can be used as electrodes in the systems and methods described herein are described, for example, in U.S. Pat. No. 9,957,163, which is hereby incorporated by reference in its entirety.

In some embodiments, the porous dendritic graphite foam can comprise a three-dimensional substrate having porous struts radiating from the surfaces of the substrate. The struts can radiate from the outer surface of the substrate, as well as from the surfaces of the pores permeating the substrate. Exemplary struts include dendrites, which include branched structures and acicular structures radiating from the substrate. As used herein, the term “ramified” refers to object bearing dendritic structures. The struts can be attached to the substrate at a single point of attachment, and individual struts are not connected to other struts. The porous dendrites can have an average pore size from 1-10,000 nm, 1-5,000 nm, 1-2,500 nm, 1-2,000 nm, 1-1,500 nm, 1-1,000 nm, 10-1,000 nm, 100-1,000 nm, 100-500 nm, 500-1,000 nm, or 500-2,000 nm.

The substrate and struts can include materials such as graphite, conductive metals, silicon and conductive polymers, i.e., electrically conducting materials with or without external stimuli. Exemplary conductive metals include copper, nickel, iron, cobalt, gold, platinum, rhodium, and mixtures thereof. Exemplary conductive polymers include poly(pyrrole), poly(acetylene), poly(phenylene vinylene), poly(thiophene), poly(3,4-ethylenedioxythiophene), poly(aniline), poly(phenylene sulfide), and mixtures thereof. In some instances, the substrate and struts may be made of the same material, wherein in others the substrate and struts are made of different materials. Three dimensional substrates include those in which the shortest dimension is at least 10 μm, at least 100 μm, at least 200 μm, at least 300 μm, at least 400 μm, at least 500 μm, at least 600 μm, at least 700 μm, at least 800 μm, at least 900 μm, or at least 1,000 μm thick.

The porous dendritic graphite foam may be a three-dimensional foam. Three-dimensional foams can have an average pore size from 1-1,000 μm, 10-1,000 μm, 10-500 μm, 50-500 μm, or 100-500 μm. The porous dendritic graphite foam can have a multilevel porosity, for instance a core level having a first porosity, and a shell level having a second porosity. The core can have an average pore size from 1-1,000 μm, 10-1,000 μm, 10-500 μm, 50-500 μm, or 100-500 μm. The core can include materials such as graphite, conductive metals, silicon and conductive polymers. In some instances, the pores in the shell are smaller than the pores in the core, for instance, the shell can have an average pore size that is less than 50%, 40%, 30%, 20%, 10%, 5%, or 1% the average pore size of the pores in the core. In some embodiments, the shell portion has an average pore size from 1-100 μm, 1-50 μm, 1-25 μm, 2-25 μm, 2-15 μm, 2-10 μm, 2-8 μm, 2-5 μm, 5-25 μm, 5-15 μm, 5-10 μm or 5-8 μm. The shell can include materials such as graphite, conductive metals, silicon and conductive polymers. In some instances, the core and the shell are made from the same materials, whereas in other cases the core is made of a different material than the shell. In certain embodiments, the core, shell, and dendrites are all porous graphite. In some embodiments, the core, shell, and/or the dendrites can further include nickel, copper, of mixtures thereof. When the shell and core are the same material, the two levels will typically have different porosities. However, the shell and core are different materials, they may have the same porosities, or different porosities.

The porous dendritic graphite foam can be characterized by high surface area. For instance, the foam can have a BET surface area of at least 5.0 m²/g, at least 5.5 m²/g, at least 6.0 m²/g, at least 6.5 m²/g, at least 7.0 m²/g, at least 7.5 m²/g, at least 8.0 m²/g, at least 8.5 m²/g, at least 9.0 m²/g, at least 9.5 m²/g, or at least 10.0 m²/g. In some instances, the structures can have an areal density of at least 0.01 mg²/cm, at least 0.05 mg²/cm, at least 0.10 mg²/cm, at least 0.15 mg²/cm, at least 0.20 mg²/cm, at least 0.25 mg²/cm, at least 0.30 mg²/cm, at least 0.35 mg²/cm, at least 0.40 mg²/cm, at least 0.45 mg²/cm, or at least 0.50 mg²/cm. In some embodiments, the substrate can have a volumetric surface area of at least 0.01 m²/cm³, at least 0.05 m² cm³, at least 0.10 m²/cm³, at least 0.15 m²/cm³, at least 0.20 m²/cm³, at least 0.25 m²/cm³, at least 0.30 m²/cm³, at least 0.35 m²/cm³, at least 0.40 m²/cm³, at least 0.45 m²/cm³, at least 0.50 m²/cm³, at least 0.55 m²/cm³, at least 0.60 m²/cm³, at least 0.65 m²/cm³, at least 0.70 m²/cm³, at least 0.75 m²/cm³, at least 0.80 m²/cm³, at least 0.85 m²/cm³, at least 0.90 m²/cm³, at least 0.95 m²/cm³, or at least 1.0 m²/cm³.

The porous foam can also be made of dendritic structures grown on a solid surface. Exemplary struts include dendrites, which include branched structures and acicular structures radiating from the substrate. As used herein, the term “ramified” refers to object bearing dendritic structures. The struts can be attached to the substrate at a single point of attachment, and individual struts are not connected to other struts. The porous dendrites can have an average pore size from 1-10,000 nm, 1-5,000 nm, 1-2,500 nm, 1-2,000 nm, 1-1,500 nm, 1-1,000 nm, 10-1,000 nm, 100-1,000 nm, 100-500 nm, 500-1,000 nm, or 500-2,000 nm. The struts can radiate from the outer surface of the solid substrate. The substrate and struts can include materials such as graphite, conductive metals, silicon and conductive polymers, i.e., electrically conducting materials with or without external stimuli. Exemplary conductive metals include copper, nickel, iron, cobalt, gold, platinum, rhodium, and mixtures thereof. Exemplary conductive polymers include poly(pyrrole), poly(acetylene), poly(phenylene vinylene), poly(thiophene), poly(3,4-ethylenedioxythiophene), poly(aniline), poly(phenylene sulfide), and mixtures thereof. In some instances, the substrate and struts may be made of the same material, wherein in others the substrate and struts are made of different materials. Three dimensional substrates include those in which the shortest dimension is at least 10 μm, at least 100 μm, at least 200 μm, at least 300 μm, at least 400 μm, at least 500 μm, at least 600 μm, at least 700 μm, at least 800 μm, at least 900 μm, or at least 1,000 μm thick.

The BET surface area, areal density, and volumetric surface area can be determined using the 5-point BET surface area test, such as performed by Pacific Surface Science Inc. Samples are prepared with nitrogen gas at 200° C. for 2 hours before test. The 5-point BET test is carried out by nitrogen adsorption at 77K. To obtain data with different units shown, the planar area, mass, and volume of a sample can be combined with the total surface area of the sample (as provided by Pacific Surface Science Inc.).

The three-dimensional porous dendritic graphite foam having porous struts radiating from the surfaces of the foam can be obtained by depositing struts on the surface of a conductive substrate. The conductive substrate can be a commercially available metal foam, for instance a nickel foam, a copper foam, an iron foam, a zinc foam, an aluminum foam, or a tin foam. In some embodiments, the substrate can be a multilayered three-dimensional substrate, for instance a core-shell substrate. In some embodiments, the substrate can be a solid substrate. The substrate can be immersed in an electrolyte solution, wherein the electrolyte solution is in electrical communication with an electrode. The electrolyte solution can include metal ions, such as copper ions, nickel ions, cobalt ions, and mixtures thereof. The ions can be provided in the form of metal salts. An electric current can be applied via the electrode in order to precipitate dissolved ions onto the surfaces of the substrate in the shape of dendritic structures.

The size and shape of the dendritic structures can be tuned by controlling the parameters of the electrochemical deposition. In some instances, the electrodeposition is conducted at an applied current of at least −25 mA, at least −50 mA, at least −75 mA, at least −100 mA, at least −125 mA, at least −150 mA, at least −175 mA, or at least −200 mA. The electrodeposition can include an applied voltage from −2.5 V-2.5 V, from −2.0 V-2.5 V, from −1.5 V-2.5 V, from −1.0 V-2.5 V, from −1.0 V-2.0 V, or from −1.0V-1.9V. The electrodeposition can include depositing on the substrate from 25-500 C/in², from 25-400 C/in², from 25-300 C/in², from 50-300 C/in², from 50-200 C/in², from 50-150 C/in², from 75-150 C/in², from 75-125 C/in², from 100-125 C/in², relative to the surface area of the substrate.

In some embodiments, the electrodeposition can be conducted over a series of electrodeposition cycles. After a period of electrodeposition, the substrate is rotated relative to the electrode, followed by additional electrodeposition. The substrate can be rotated 30°, 60°, 90°, 120°, 150°, or 180° relative to the electrode, and can be rotated along one or two axes. For instance, the substrate can be rotated 180° along two axes. The electrodeposition can be conducted over at least 2, 3, 4, 5, 6, 7, 8, 9 or 10 cycles. In some instances, the current is discontinued during the rotation phases, while in others, the substrate is rotated while the current is still applied. In yet other embodiments, the substrate is continuously rotated over the course of electrodeposition. By rotating the substrate, a more uniform deposition of dendrites can be achieved.

After depositing the dendrites on the substrate, the substrate/dendrites can be annealed to give a dendritically porous foam. Typical annealing conditions include heating the dendritic substrate under a gas flow, for instance hydrogen, nitrogen, and mixtures thereof. Exemplary gases include H₂ at 1-10 sccm, 2-8 sccm, 3-7 sscm or 5 sccm, in combination with N₂ at 1-100 sccm, 10-90 sccm, 25-75 sccm, 40-60 sccm, or 50 sccm. The annealing can be conducted at a temperature between 500-1,500° C., between about 750-1,250° C., or between about 900-1,100° C. The heating can be performed for at least 1 minute, at least 2 minutes, at least 5 minutes, or at least 10 minutes, for instance, for about 1-20 minutes, 1-15 minutes, 2-15 minutes, 2-10 minutes, 2-8 minutes, or 3-7 minutes.

The graphite network can be obtained using chemical vapor deposition or hydrothermal deposition, or via thermal annealing of organic molecule coating. For instance, chemical vapor deposition can be performed with a carbon source, such as a C₂₋₄ hydrocarbon, including, but not limited to, ethylene, acetylene, propylene, propyne, butadiene and mixtures thereof. The deposition can be conducted using a carrier gas, for instance hydrogen. Generally, the deposition can be conducted at a temperature less than about 1,000° C., less than about 900° C., less than about 850° C., less than about 800° C., less than about 750° C., less than about 700° C., less than about 650° C., less than about 600° C., less than about 550° C., or less than about 500° C. In some embodiments, the deposition can be conducted at a temperature between about 500-1,000° C., between about 500-900° C., between about 600-900° C., between about 600-800° C., or between about 650-750° C. In some instances, the deposition is conducted at a temperature around 700° C.

The thickness of the struts can be controlled by varying the deposition conditions, such as growth time. The thickness of struts is determined by measuring the areal density of the obtained samples. The deposition can be conducted for at least 1 hour, at least 2 hours, at least 5 hours, at least 10 hours, or at least 15 hours. For instance, the deposition may be conducted for 1-20 hours, 2-20 hours, 2-15 hours, 5-15 hours, or 10-15 hours.

Examples of organic molecule coating that can be converted into graphite via thermal annealing, include sugar, polymers, resin. Generally, the annealing can be conducted at a temperature less than about 1,000° C., less than about 900° C., less than about 850° C., less than about 800° C., less than about 750° C., less than about 700° C., less than about 650° C., less than about 600° C., less than about 550° C., less than about 400° C., less than about 300° C., less than about 200° C., and less than about 100° C.

After the graphite network has been prepared, the substrate can be removed to give a dendritic graphite structure. In the case of metal foams, the substrate can be removed by etching, for instance chemical etching, such as with one or more acids. In some instances, the substrate can be removed by treatment with a mineral acid, such as HCl, HBr, HI, HF, HNO₃, H₂SO₄, H₃PO₄, and mixtures thereof, optionally in combination with one or more Lewis acids, for instance a transition metal salt such as FeCl₃, FeBr₃, BCl₃, BF₃, AlCl₃, AlBr₃, Al(OiPr)₃, SnClᵣ, TiCl₄, or Ti(OiPr)₄.

In addition to removing bacteria, the dendritic graphite foams can be combined with a variety of active materials for the removal of toxic metal ions and organic compounds from water. The toxic metal ions include lead, mercury, arsenide. The organic compounds include pesticide and Per- and polyfluoroalkyl substances (PFAS). As used herein, such materials can be designated dendritic graphite foam composites (“RPGM”). Suitable active materials include sulfide compounds like MoS₂, NiS, Fe₂S₃, Na₂S, CaS, CuS, ZnS, and Ag₂S, manganese oxides like MnO₂ and Mn₃O₄, cobalt oxides like Co₃O₄, ruthenium oxides like NiO, ferric oxides like Fe₃O₄, as well as mixed metal oxides like NiCo₂O₄ and MnFe₂O₄. The active material may be deposited on the surface of the dendritic graphite foams as nanoparticles using conventional techniques, for instance hydrothermal reaction. The loading efficiency of the dendritic graphite foams is substantially improved over conventional foams. Conventional foam composites can be designated “GM.” For instance, the active material can be loaded in an amount greater than 0.5 mg/cm², greater than 1.0 mg/cm², greater than 1.5 mg/cm², greater than 2.0 mg/cm², greater than 2.5 mg/cm², greater than 3.0 mg/cm², greater than 3.5 mg/cm², greater than 4.0 mg/cm², greater than 4.5 mg/cm², or greater than 5.0 mg/cm². After loading, the active material can constitute at least 50%, at least 60%, at least 70%, at least 80%, or at least 90% of the total weight of the graphite/active material composite. In some embodiments, the active material is loaded in an amount greater than 3 mg/cm² and constitutes at least 70% of the total weight of the graphite/active material composite. In other embodiments, the active material is loaded in an amount greater than 3.5 mg/cm² and constitutes at least 75% of the total weight of the graphite/active material composite. In preferred embodiments, the active material is loaded in an amount greater than 4.0 mg/cm² and constitutes at least 80% of the total weight of the graphite/active material composite.

### EXAMPLES

The invention will be described in greater detail by way of specific examples. The following examples are offered for illustrative purposes and are not intended to limit the invention in any manner. Those of skill in the art will readily recognize a variety of non-critical parameters which can be changed or modified to yield essentially the same results.

### Example 1. Portable Bulk-Water Disinfection by Live Capture of Bacteria with Divergently Branched Porous Graphite in Electric Fields

### SUMMARY

Easy access to clean water is essential for the development and function of modern society. However, it remains arduous to develop energy-efficient, facile, and portable water treatment systems for point-of-use (POU) applications, which is particularly imperative for the safety and resilience of society during extreme weather and critical situations. In this example, we propose and validate a meritorious working scheme for water disinfection via directly capturing and removing pathogen cells from bulk water using strategically designed three-dimensional (3D) porous dendritic graphite foams (PDGFs) in a high-frequency AC field. The prototype, integrated in a 3D-printed portable water-purification module, can reproducibly remove 99.997% E. coli bacteria in bulk water at only a few voltages with among the lowest energy consumption of 435.5 J·L⁻¹. The PDGFs, costing $1.47 per piece, can robustly operate at least 20 times for more than 8 hours in total without functional degradation. Furthermore, we successfully unravel the involved disinfection mechanism with one-dimensional Brownian dynamics simulation. The system is practically applied that brings natural water in Waller Creek at UT Austin to the safe drinking level. This research, including the working mechanism based on dendritically porous graphite and the design scheme, inspires a future device paradigm for POU water treatment.

### Results and Discussion

Bacteria are widely present in fresh water, such as rivers, lakes, ponds, and streams. They include Escherichia coli, Shigella, Salmonella enterica, Vibrio cholerae, Vibrio parahaemolyticus, and Bacillus, most of which can result in waterborne diseases. Among various bacteria, due to the prevalence and the proportionality to other types of bacteria, E. coli is often used for evaluating water quality and water-treatment performance. Therefore, we carried out systematic studies evaluating bacterial disinfection by using E. coli bacteria as a model system followed by the testing of shigella, another bacteria also widely found in natural water.

To capture bacteria from water, we explore the interactions between electric fields and the electrically polarized bacterial cells. When micro/nanoparticles are subjected to a high-frequency non-uniform AC electric field, they can be readily aligned and transported to either the highest or the lowest electric-field gradient. In water medium, the electric-field-particle interaction is governed by both the Maxwell-Wagner (MW) electric polarization of the micro/nanoobject and the electric double layer formed near the surface of the object in response to the MW polarization. The alignment torque (τₑ) in a uniform electric field, e.g., at a location far from two parallel electrodes, is given by Equation (1),

$$│ {τ}_{e} = - \frac{1}{2} {E}_{0}^{2} R e ( {α}_{∥} - {α}_{⊥} ) sin θ cos θ \hat{z} , \qquad ( 1 )$$

where E₀ is the amplitude of the electric field, a_{∥} and a_{⊥} are the total complex electric polarizability of the particle and electric double layer along the long and short dimensions, respectively, and θ is the angle between the long axis of the object and the electric field. In a non-uniform electric field, e.g., at a position close to the electrodes, a particle can be transported in the direction either toward or away from the highest electric field gradient, which depends on the relative electric polarization of the particle and the suspension medium. The associated force is the so-called dielectrophoresis (DEP). A DEP force (<F_{DEP}(t)>) can be calculated as follows,

$$< {F}_{DEP} ( t ) > = \frac{1}{2} R e ( \underline{α} ) ∇ {E}_{r m s}^{2} , \qquad ( 2 )$$

where a is the complex total polarizability in the direction of the electric-field gradient for an object aligned by the field; it is determined by both the MW electric polarizability of the particle and the electric-double-layer polarizability. Eᵣₘₛ is the root mean square of the electric field intensity. When the AC frequency is above 100 kHz, the electric-double-layer effect can be considered negligible,⁴¹ and the DEP force is determined by the MW electric polarization, depending on the electric conductivities and permittivities of both the micro/nanoobject and the water medium.

To this end, in microfluidic settings, electric-field-based manipulation has been explored for transporting, aligning, rotating, separating, and sorting various micro/nanoentities, including biological cells, bacteria, and inorganic micro/nanowires, ribbons, spheres, and nanoporous structures. However, the manipulations that have been demonstrated are realized in a small region, usually a few hundreds of micrometers defined by the employed microelectrodes, and the volume is limited to milliliters to tens to hundreds of microliters, which are not suitable for bulk water treatment. This is because when a physical dimension is changed, the dominating physics and challenges are often changed as well. It is intriguing to explore if the electric manipulation achieved on small scales can be utilized for macroscopic application. With the understanding of the challenge in this field and our in-depth knowledge of electric-field-material interactions, we proposed a device concept based on PDGF materials and an associated fabrication approach.

We begin by exploring the strong motion response of E. coli cells to a non-uniform AC electric field created from microelectrodes to show the feasibility in aligning, capturing, and releasing bacterial cells. As depicted in FIGS. 8A-8D, when an AC voltage of 10 MHz is applied across two parallel microelectrodes, the E. coli cells quickly align in the electric-field direction, transport, and attach to the edges of the microelectrodes, the location of the highest electric-field gradient. In addition to the DEP forces that can effectively attract bacteria towards the microelectrodes, there are two other factors that govern the bacteria's transport behaviors: 1) the locomotion of E. coli without tumbling; 2) the passive diffusion of E. coli. The contribution of all these three factors will be evaluated and discussed based on the understanding obtained from Brownian dynamic simulation. We also note that upon the removal of the AC voltages, the E. coli cells can be readily released alive from the microelectrodes and resume their locomotion.

The above experiments conducted on a scale of hundreds of micrometers provide understandings for our exploration in bulk-water disinfection with PDGF-materials-powered DEP manipulation. The research reported in this example for water disinfection is based on exploiting electroalignment and DEP forces generated by high-frequency AC electric field for the mechanical manipulation and physical removal of bacteria in bulk still water. The bacterial cells are aligned by the electric fields, swim towards an electrode, and get captured; the leverage of the bacterium's locomotion contributes to the device's low energy consumption. In addition, the system can be portable, where there is no need for pumped water flows.

### Materials Fabrication, Device Design, and Performance Characterization

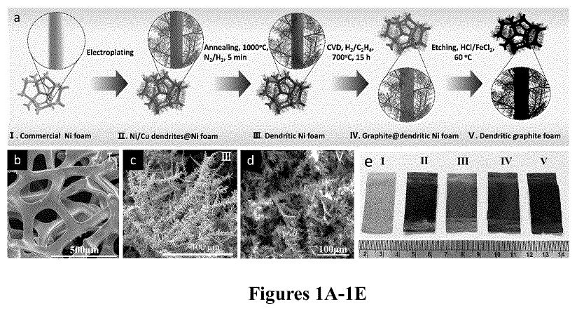

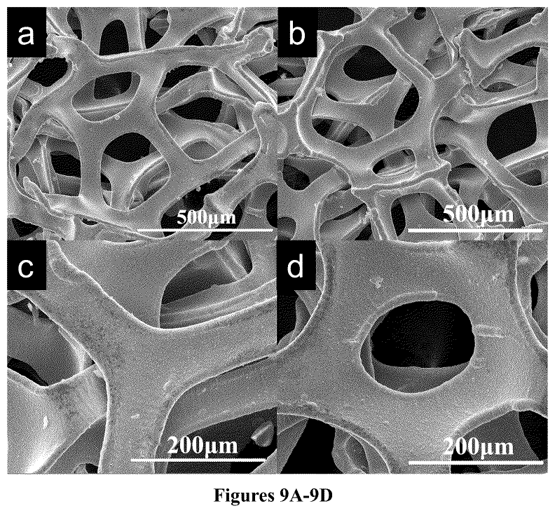

The fabrication of the PDGF-materials utilized in bacterial capture starts with the electrodeposition of porous dendritic Ni foams (PDNFs), which are applied as the catalytic templates for the conformable growth of PDGFs via chemical vapor deposition (CVD). Freestanding PDGF is obtained after selectively etching the catalytic templates, as depicted in FIG. 1A. The detailed fabrication is included in the Methods. In brief, firstly, PDNFs are made by direct electrodepositing 3D diverging nickel-copper (Ni/Cu) microbranches on a commercial Ni foam [NF, FIG. 1B, FIG. 1E (I), FIGS. 9A-9D]. The Ni/Cu microbranches grow densely on the entire 3D surface of the Ni foam in an electrolyte consisting of copper sulfate (CuSO₄, 0.0025 M), nickel chloride (NiCl₂, 0.1 M), and boric acid (H₃BO₃, 0.323 M) [FIG. 1C, FIG. 1E (11)]. After thermal annealing to strengthen the obtained dendritic foam [FIG. 1E (111)], thin graphite is synthesized conformably on the PDNF via a CVD reaction in a gas mixture of C₂H₄ (10 sccm) and H₂ (20 sccm) at 700° C. for 15 hours [FIG. 1E (IV)]; The PDNF serves as both the catalyst and template. Finally, we obtain highly branched PDGF superstructures after etching the metal cores in a FeCl₃/HCl solution [FIG. 1D, and FIG. 1E (V)].

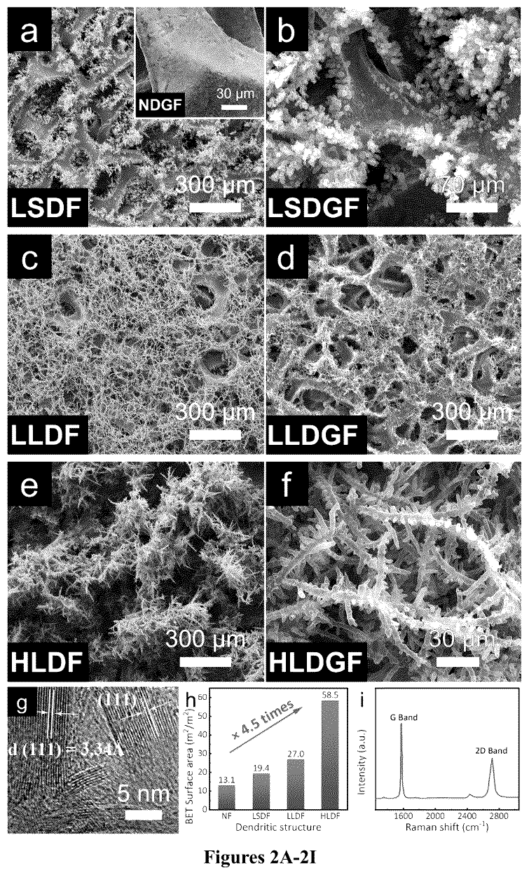

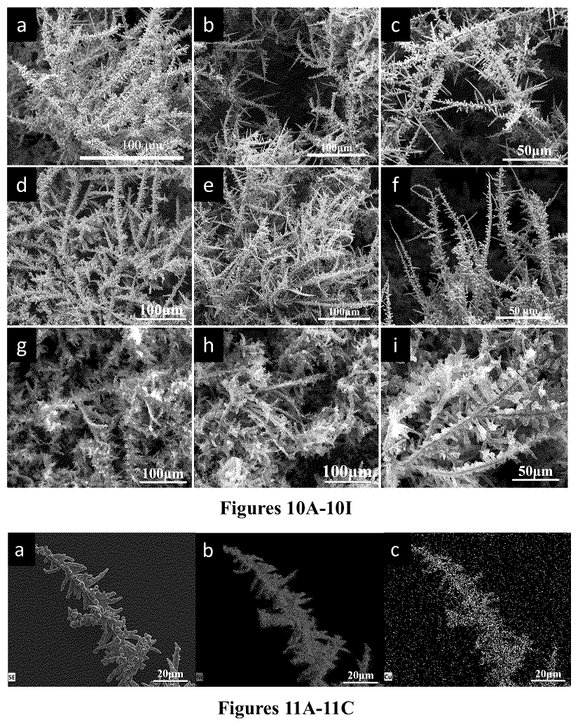

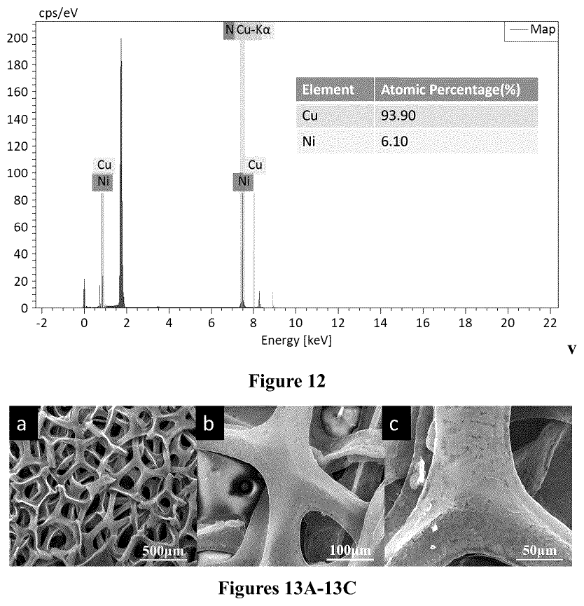

Different from previous research, we carry out one-step fabrication of bimetal Ni/Cu microbranches on commercial Ni foams for the catalytic growth of 3D dendritically porous graphite. With systematic optimization, we obtain PDNFs with a series of distinct morphologies (FIGS. 2A-2I), ranging from low-density short-branched superstructures (FIG. 2A-2B) to high-density long-branched superstructures (FIG. 2E-2F). It is found that the branch formation exhibits a high correlation with the presence of Cu²⁺ ions (>0.001 M) in the nickel-chloride electrolyte Ni²⁺>0.1 M, Cl⁻>0.1 M) that leads to the ramified Cu—Ni superstructures deposited on the Ni foam. The morphology, length, diameter, and density of the Cu—Ni microbranches depend on a series of electroplating conditions, including applied electric potential, electrolyte composition and concentration, pH values, as well as electrodeposition time. For instance, after optimization, multitudes of long Ni—Cu microbranches with high aspect ratios (1˜3 μm in diameter, 100˜200 μm in length) can grow on the interconnected microstruts of the Ni foam (FIGS. 2E-2F and FIGS. 10A-10C). The as-obtained microbranches include uniformly distributed Ni (93.90 atom %) and Cu (6.10 atom %), as shown by the Energy-dispersive X-ray spectroscopy (EDX) [FIGS. 11A-11C and 12]. Both Ni and Cu are catalysts for graphene and thin graphite growth, and it is found the presence of Cu in Ni can consistently enhance the crystallinity and electric conductivity of thin graphite grown in the next step. Furthermore, the diverging microbranches randomly orient, extend, and fill the empty interconnected 3D microvoids of the 3D Ni foam. The fabrication of the microbranches not only increases the specific surface area of the template foam by 4.5 times, i.e., from 13.1 (Ni foam) to 58.5 m²/m² (PDNF) [FIG. 2H], offering extensive 3D interfacial contact to bulk water in the bacterial disinfection applications, but also generates ultra-strong localized non-uniform electric fields due to the lightning-rod effect of the long microbranches; both advantages are essential for enhancing the interaction, attraction, and capture of bacterial cells from bulk water compared to that of planar electrodes.

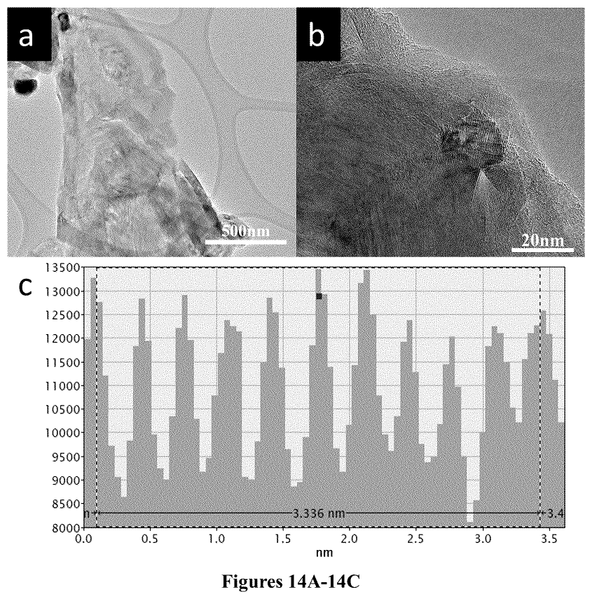

Next, freestanding PDGFs are fabricated by conformable growth on the PDNF (FIG. 10D-10F) followed by selective etching of the PDNF template in a FeCl₃/HCl solution. The PDGFs offer large arrays of high-aspect-ratio tubular graphite microbranches covalently extended from the 3D porous graphite scaffold as shown in FIG. 2F and FIG. 10G-10I. Compared to the smooth graphite foam obtained from simple commercial Ni templates (FIG. 2A, inset, and FIGS. 13A-13C), the graphitic microtubes in PDGFs replicate the morphology of the diverging Ni/Cu microbranches. The graphite is highly crystalline and scalable that 2 cm×4 cm samples can be routinely made in a research lab (HRTEM in FIG. 2G, FIGS. 14A-14C, and Raman spectrum in FIG. 2I). The fabrication only requires conventional electrodeposition and CVD techniques.

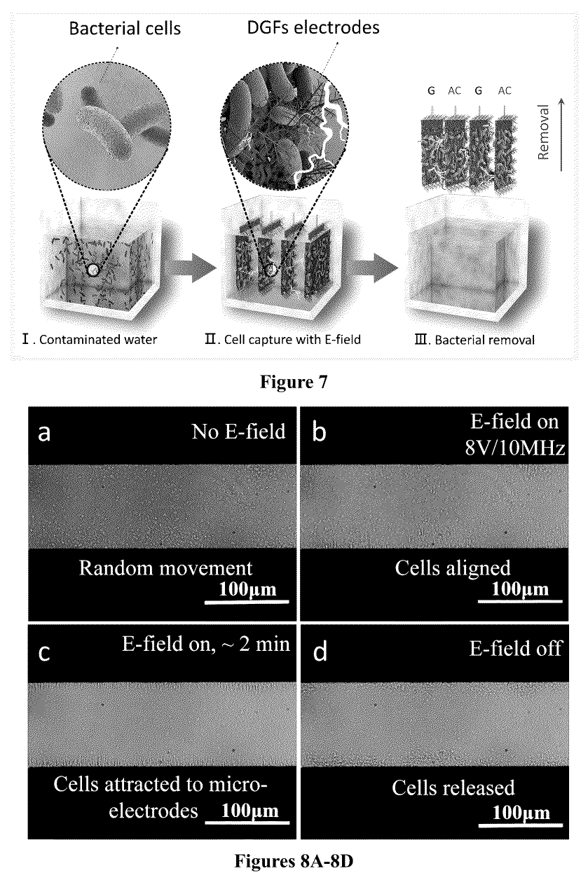

Finally, the obtained PDGFs are assembled in various configurations in a water-treatment module made by 3D printing (Details in Methods). In a typical experiment, 4 identical PDGF electrodes are assembled in a cuboid container (3×1×4, cm³) with an inter-distance of 250 μm. Next, a suspension of E. coli cells of ˜10⁶ CFU/mL prepared in biological-grade water is dispersed in the container (FIG. 7), followed by the application of an electric signal of controlled voltage, frequency, and duration to the PDGF electrodes at room temperature. The concentrations of bacteria before and after applying the electric field are determined by the standard spread-plate technique (Details in Methods). The capture efficiency is calculated from the plate-counting numbers of bacterial colonies before and after the AC-voltage treatment.

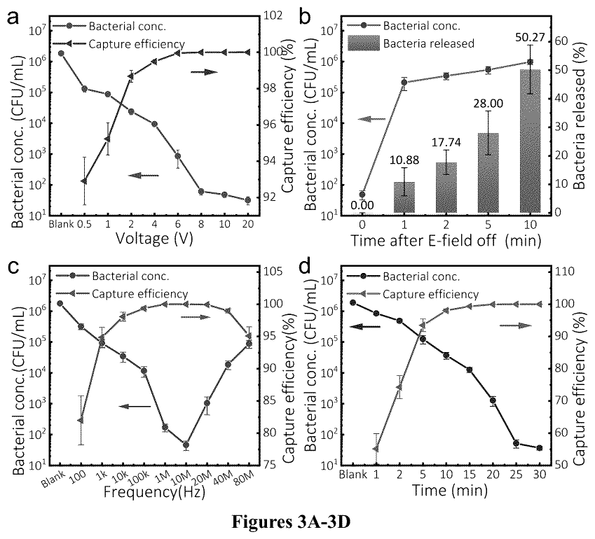

It is found at only 0.5 V and 1 V (10 MHz and 25 min), this water treatment device can already remove 92.910% and 95.230% bacterial cells, respectively. The efficiency further improves to 99.953% at 6 V, and then reaches 99.998% at 20 V (FIG. 3A). The results indicate that the strength of the electric field plays a salient role in removing the bacterial cells, agreeing with our understanding of the motion response of bacterial cells to a DEP force. We note that although the high-intensity AC field created by the highly branched porous foam could compromise the viability of bacteria, ˜50% of bacteria recovered after we release the electric field for 10 min. Recovered cells monotonously increase with release time (FIG. 3B). This study suggests that at the end of 25 min AC-field application, where almost all the bacterial cells are caught by the dendritically porous electrodes, much of the population is alive. This result agrees with the aforediscussed observation of the microelectrode manipulation of bacteria, where after removing the high-frequency AC field, the bacterial cells captured on the electrodes restore their locomotion in solution. We further conduct a control experiment using a pair of Au-on-glass planar electrodes in the same experimental condition; immediately after the retrieval of the electrode set, we carry out the plate-counting test and observe almost no bacterial removal. This control experiment indicates planar electrodes are neither effective in capturing and trapping nor lysing bacteria cells for bulk water treatment, highlighting the essential role of the dendritically porous superstructures as electrodes for powering efficient bacterial removal for water disinfection at low AC voltages. Indeed, previous works also show kilovolt-pulsed field is often required for cell lysis with electroporation in low-conductivity still water. Overall, the experimental results obtained with the PDGF electrodes (FIGS. 2F-2E) and planar microelectrodes (FIGS. 8A-8D) indicate that bacterial removal at the optimized 10 MHz is dominantly via DEP-force-assisted live cell capture owing to the highly branched porous electrodes, which has been realized on fresh still water using low AC electric voltages.

As we can achieve more than 95% disinfection at a voltage as low as 1 volt, in the following, we choose a constant AC voltage at the same order of magnitude, i.e., 8 V, for systematic characterization of the efficiency and energy consumption of the water disinfection system.

The bacterial removal depends on the AC frequency and is studied by varying the frequency from 100 Hz to 80 MHz. At each frequency, a constant AC voltage (8 V) is applied for 25 min. The efficiency rapidly increases between 100 Hz to 1 MHz and reaches a plateau at 1-20 MHz, and then slightly decreases in the range of 20 to 80 MHz (FIG. 3C). The observed decrease can be attributed to the multiple shell structure of the bacteria, where each shell has distinct dielectric properties that have been previously studied and modeled. The complex structure and variation in dielectric properties can lead to the DEP force/efficiency change at the high-frequency range.

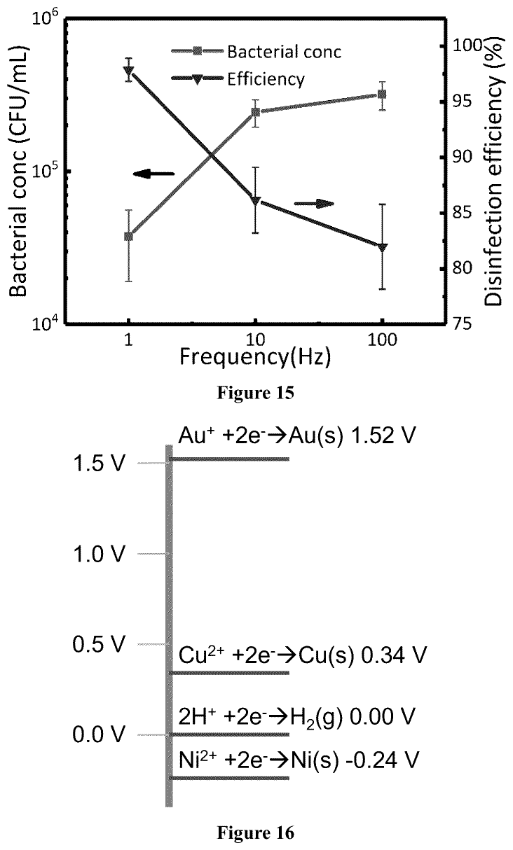

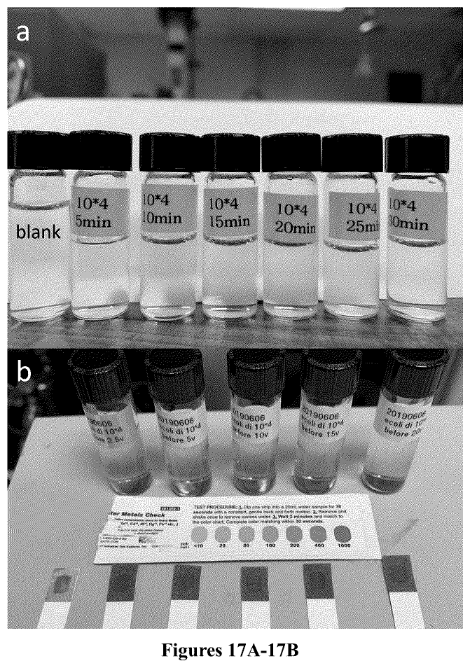

The optimized AC frequency is in the range of 1-20 MHz, e.g., 99.997% at 10 MHz. Interestingly, when the AC frequency changes from 100 Hz to 1 Hz, the device performance increases (FIG. 15), though, the disinfection is not effective as that at 10 MHz (same voltage and duration), and the working mechanism is distinct. We notice that the application of DC or low-frequency AC signals often damages metal electrodes. For instance, Au microelectrodes can be easily damaged at approximately 3V (FIG. 16). For the metallic porous dendritic Ni foams (PDNF) or graphite@dendritic Ni foam, even at a high frequency of 10 MHz where the electrochemical reaction can be substantially suppressed, the foams still undesirably release metallic ions that introduces ionic contaminants (FIGS. 17A-17B). Indeed, it is imperative to employ graphite foams and AC voltages for contamination-free bacterial removal from water.

Next, we evaluated how the efficiency of bacterial removal depends on the time of voltage application. The removal efficiency rapidly increases with time at 8 V, 10 MHz in the first 15 min (FIG. 3D), before it gradually reaches 99.932% at 20 min, and 99.998% at 30 min. The slow increase of the efficiency in the second 15 min can be attributed to the depletion of bacterial cells around the PDGF electrodes when most of them have been captured. The bacterial removal slowly approaches a plateau after 25 min; we consider 25 min as the effective removal time. The removal efficiency is almost the same for bacteria with concentrations from ˜3×10⁷ to ˜2×10⁵ CFU/mL (Table 1).

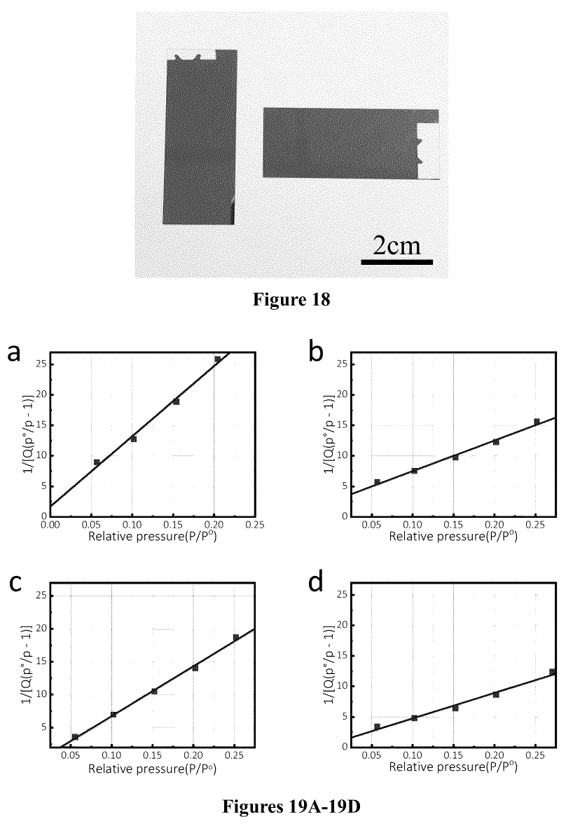

It is highly interesting to understand how the disinfection efficiency depends on the morphologies of PDGF electrodes, i.e., the ramification degree and density of the microbranches. To address this question, we fabricate four types of 3D PDGFs, as well as a planar Au/Cr(50 nm/5 nm)-coated glass electrode as the control (FIG. 18). After systematically tuning the electrodeposition parameters, including the concentrations of nickel chloride (NiCl₂) and copper sulfate (CuSO₄) in the electrolyte, we successfully obtain four types of PDGFs. They are low-density-short-branched DGFs (LSDGFs, FIG. 2A-2B), low-density-long-branched DGFs (LLDGFs, FIG. 2C-2D), high-density-long-branched DGFs (HLDGFs, FIGS. 2E-2F), and non-dendritic graphite foams (NDGFs, FIG. 2A, inset and FIGS. 13A-13C). The specific surface areas of the foams obtained via measurements of their templates are 19.4, 27.0, 58.5, and 13.1 m²/m², respectively (FIG. 2H and FIGS. 19A-19D), where it can be found that the HLDFs offer the largest specific surface area, more than four folds of a commercial Ni foam. All 5 electrodes, including the four types of graphite foams and the Au/Cr glass, are tested at 8 V, 10 MHz for 25 min.

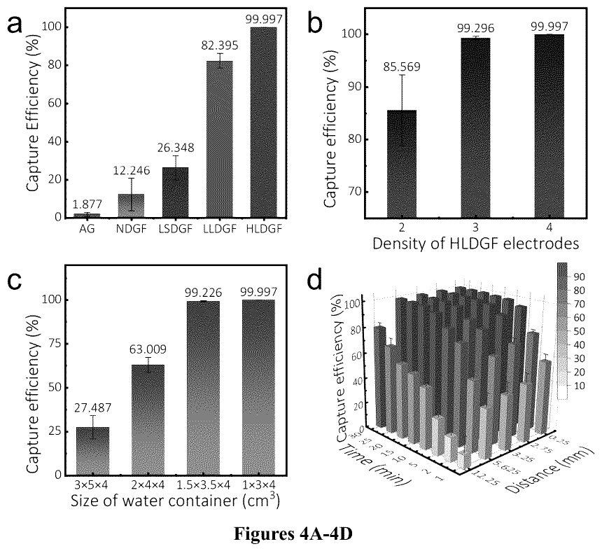

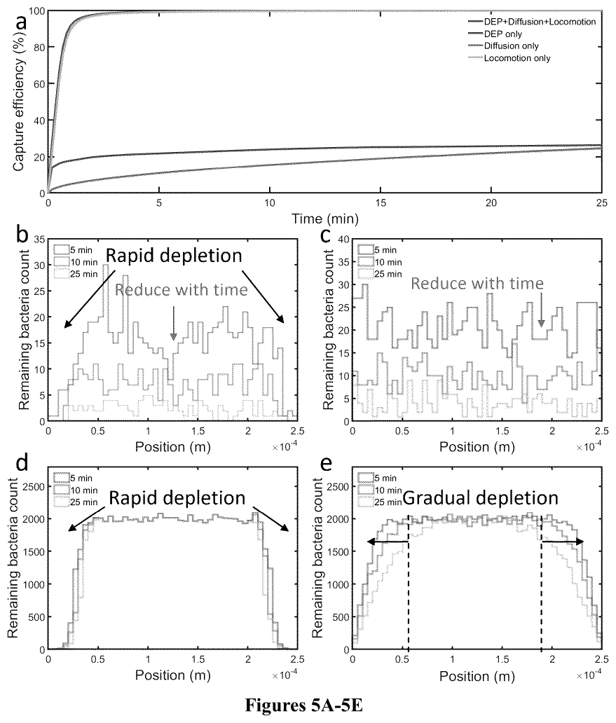

As discussed earlier, the planar Au-on-glass electrode almost does not remove bacteria; the efficiency is only 1.877%. An improved but still a rather low efficiency of 12.246% is obtained from the NDGFs electrode, the graphite foam made of smooth interconnected microstruts. In contrast, the ramified graphite electrodes with microbranched surfaces, LSDGFs, LLDGFs, and HLDGFs, demonstrate much amplified effect in bacterial capture and removal. In particular, the HLDGFs with high-density long branches and the largest specific surface area offer the highest E. coli removal efficiency of 99.997%, followed by that of low-density-long-branched LLDGFs at 82.395%. The LSDGFs with high-density short branches show the lowest efficiency of 26.348% among the three ramified graphite foams (FIG. 4A). These results unambiguously unveil the critical roles of the density and morphology of a dendritic foam for bacterial disinfection—the denser and longer of the branches, the higher the bacterial removal efficiency.

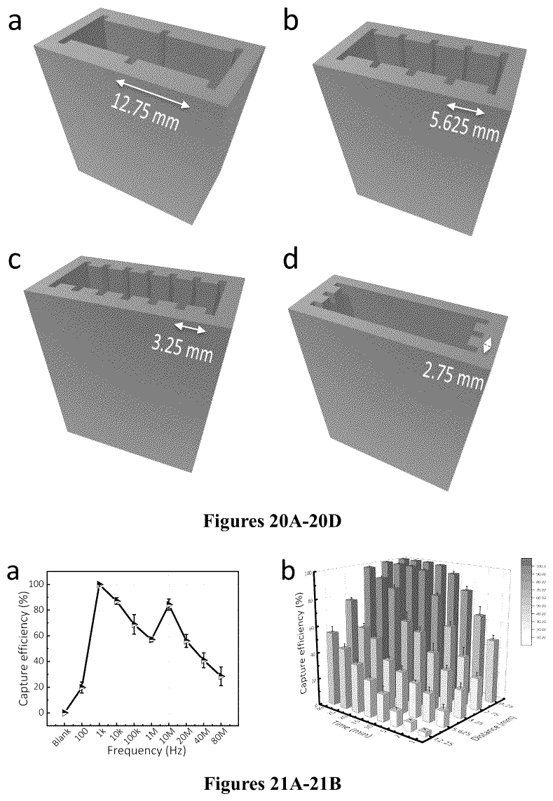

Finally, we evaluate several important geometric factors of the water-treatment system, including the density of the HLGDF electrodes, volume of water, and electrode distance. It is found that the bacterial removal efficiency (FIG. 4B) improves from 85.569% to 99.997% by simply increasing the number of HLGDF electrodes from 2 to 4 (8V, 10 MHz). The efficiency also monotonically increases with the reduction of water volume, i.e., 27.487%, 63.009%, 99.226%, and 99.997% for water in containers of 3×5×4, 2×4×4, 1.5×3.5×4, 1×3×4 cm³, respectively (FIG. 4C). Furthermore, by reconfiguring the assembly of the HLDGFs electrodes to narrow their spacing (FIG. 20A-20D), as shown in FIG. 4D, consistent improvement of the bacterial removal efficiency is obtained. In all tests, the removal of bacteria monotonically improves with the duration of electric-field application.

In addition to using E. coli as a model pathogen for water disinfection, we apply the same strategy for the removal of Shigella, another type of bacteria that is commonly found in natural water bodies but does not exhibit similar locomotion as that of E. coli (FIGS. 21A-21B). Similar dependencies of removal efficiency on the distance, voltage, and time are observed, except that the frequency-dependent is different from that of E. coli cells. At 1 kHz, the removal of Shigella is close to 100%.

### Numerical Simulation: Shedding Light on the Water Disinfection Mechanism

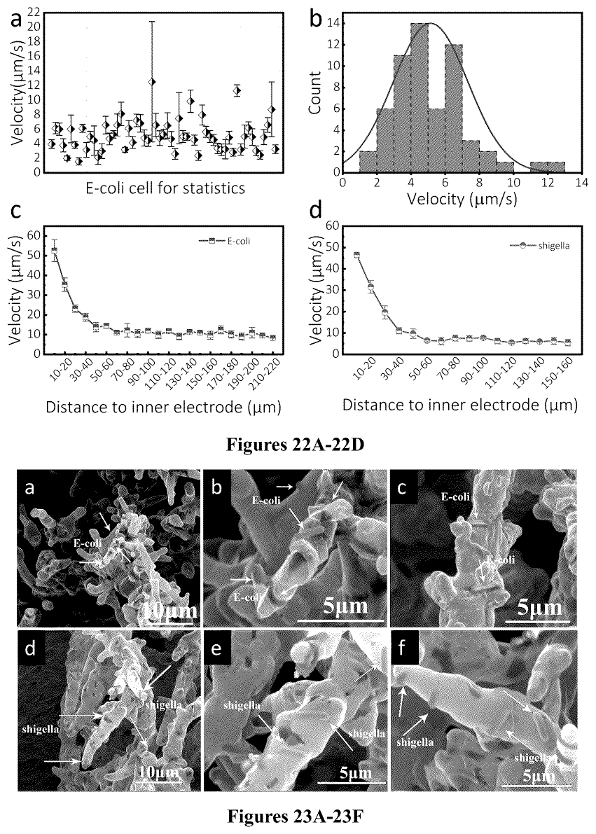

To gain insights into the working mechanism of the demonstrated bacterial removal, which is governed by the DEP force, bacterial locomotion, and passive diffusion, we carry out Brownian dynamic simulation. The simulation is built on a 1D Brownian dynamics model, and the aim is to provide understanding. The electric-field distribution is calculated by using COMSOL. Specifically, first, 100000 bacteria are randomly seeded in the simulation domain between two electrodes. Each bacterium cell is then assigned a constant locomotion speed and direction. For E. coli cells, the locomotion speeds follow a Gaussian distribution with speed and deviation given by μ=5.1 μm/s and σ=2.2 μm/s, respectively, which are determined by experimental measurement in FIGS. 22A, 22B. The motion of each bacterial cell is governed by Equation (3) in the following,

$$\dot{X} ( t ) = \frac{D}{{k}_{B} T} {F}_{D E P} ( X ) + {V}_{loco} + \sqrt{2 D} R ( t ) , \qquad ( 3 )$$

where X(t), D, F_{DEP}(X), V_{loco} and R(t) are the coordinate location, diffusivity of a bacterium, dielectrophoresis force, locomotion velocity of the E. coli and a delta-correlated stationary Gaussian process that follows [symbol] R(t) [symbol] =0 and [symbol] R(t)R(t′) [symbol] =δ(t−t′). The time step, dt, is selected to be much larger than the relaxation time of a bacterium's Brownian motion, which guarantees the simulation is overdamped. The detail is included in Supporting Information Note 2, which provides insights to the contributions of the three coexisting processes, i.e., bacterial locomotion, DEP attraction, and passive diffusion in water disinfection. It is found, the locomotion of bacteria makes the greatest contribution for the bacterial removal, which is assisted by the AC field alignment towards the electrodes (FIGS. 5A, 5B). The DEP attraction force is another salient process for bacteria removal, where it is most effective in the vicinity of the electrode of ˜50 μm (1D simulation) that rapidly deplete bacterial cells within the region and capture them on the microbranched porous electrodes (FIG. 5C). For bacterial cells located beyond the DEP trapping region near the electrodes, they have to swim actively (FIG. 5B) or diffuse passively into the trapping regions to be captured by the electrodes (FIG. 5D). The AC field alignment readily assists the swimming direction towards the electrodes, which enhances the bacterial capture efficiency. The simulation also suggests, for the non-motile shigella, where the directional swimming is not viable as that in FIG. 5B, the disinfection mechanism at the optimized frequency of 1 kHz is different from that at 10 MHz. We note that strong electrokinetic flows occur at 1 kHz on electrodes; this effect could assist the transport of the bacteria cells in the center to the DEP-active region for trapping.⁵⁷ Here, all the simulations are obtained from a 1D model, which facilitates understanding of the manipulation and contributing factors in the water treatment. To obtain quantitative insights, 3D simulation with sophisticated modeling of the ramified microelectrodes used in experiments is necessary.

The DEP-governed bacterial disinfection mechanism, as suggested in the simulation, is well supported by experimental observations (FIGS. 3A-3D and 4A-4D). It is found that the efficiency of bacterial removal systematically increases with the applied voltage and time (FIGS. 3A, 3D), as well as the ramification and density of DGFs electrodes (FIGS. 4A, 4D).

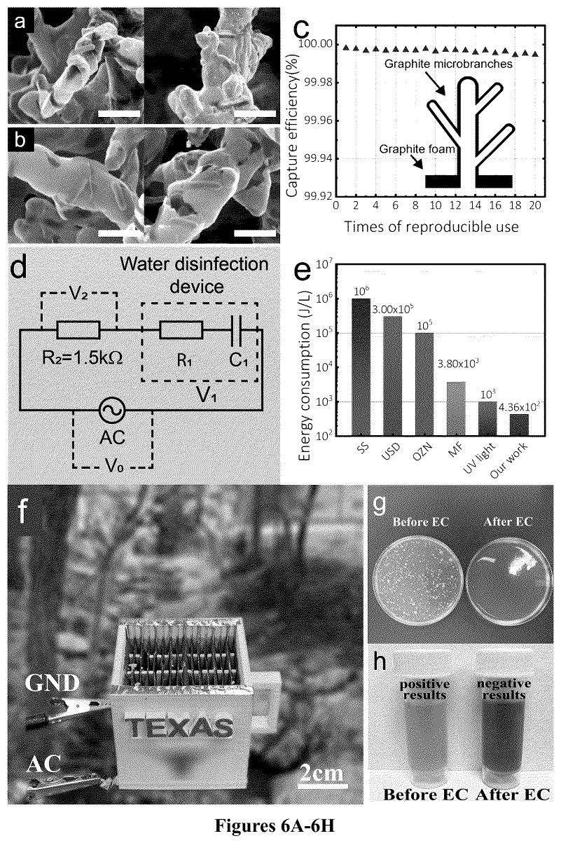

The simulation results also suggest that the DEP effect, much amplified by the highly branched HLGDFs electrodes, is distinct from DC-field-based electroporation that lyses bacteria via membrane disruption. Here the DEP force, generated via low-voltage high-frequency AC electric field, disinfects water primarily by aligning, attracting, and capturing bacterial cells from contaminated water with the high-density-microbranched PDGFs. The PDGFs are essential in creating strong non-uniform AC electric fields that greatly intensify interactions with the bacterial cells in contrast to simple planar electrodes. This DEP-based bacterial manipulation, which has been studied using microscale electrodes in this and previous works (FIGS. 8A-8D), is now applied for bulk water treatment and proved to be effective and advantageous in its low voltage and compatibility with freshwater in nature. As shown in the SEM images, after the water treatment, a large number of E. coli cells are found attaching to the microbranches of the PDGFs (FIG. 6A and FIG. 23A-23C), so do shigella cells (FIG. 6B, and FIG. 23D-23F). Here the PDGF electrodes are directly retrieved from water with applied AC voltages for the characterization.

### Robust Device and Low Energy Consumption

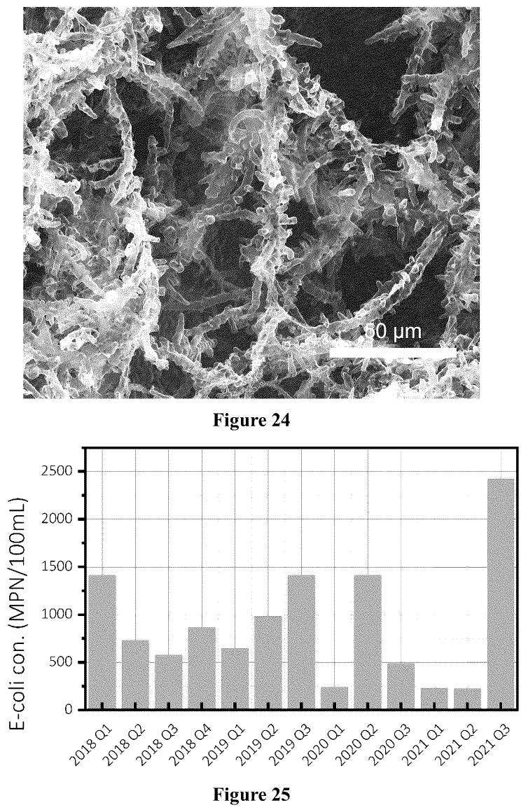

Excellent robustness of the system is important for its practical use in water purification. We repeatedly employ the same system, i.e., the same PDGF electrodes and experimental conditions, for removing bacteria 20 times. The total working duration is more than 8.3 hours, and we obtain over 99.990% bacterial removal in all 20 tests (FIG. 6C). This reliable performance can be attributed to the durable porous superstructures of the ramified PDGFs consisting of tubular microbranches covalently integrated with the 3D porous frameworks, as shown in FIG. 6C inset. Scanning electron microscopy (SEM) imaging further confirms the well-maintained, highly ramified microstructures of the PDGFs after the 8.3-hour application (FIG. 24).

The next important performance is how well the water-treatment system operates in energy consumption. We evaluate this technical parameter at an optimized experimental condition. The testing circuit is constructed as shown in FIG. 6D, in which the current and voltage can be measured at different locations in the circuit during water treatment, where V₀, R₂, R₁, and C₁ are the applied voltage, external resistor of 1500Ω, and measurable resistance and capacitance, respectively. An energy consumption of 435.5 J/L is determined. This value is several-orders-of-magnitude lower compared to those of various cutting-edge water disinfection technologies that have received immense research interest, including solar steaming (SS, 10⁶ J·L⁻¹), ultrasound disinfection (USD, ˜3×10⁵ J·L⁻¹), ozonation (OZN 1.3×10³−1.0×10⁵ J·L⁻¹), membrane filtration (MF, 6.8×10²−3.8×10³ J·L⁻¹), and ultraviolet light disinfection (UV light, ˜1 to 3×10³ J·L⁻¹) [FIG. 6E]. The advantageous low energy consumption can be attributed to the working principle exploited in this system, where the electric energy is largely used for physically aligning and translocating bacterial cells in water to electrodes. In comparison, for instance, the various solar-steaming techniques that have received remarkable attention require intrinsically high energy consumptions that involve liquid-to-vapor phase transition of water with an enthalpy of 2.46×10⁶ J/L (44.2 kJ·mol⁻¹, 101325 Pa, 25° C.). The measured energy consumption suggests that even by utilizing a standard solar panel with an energy-conversion efficiency of 10%, the reported water-disinfection module consumes much less energy than most of the aforediscussed technologies, which is desirable in addition to its advantageous portable bulk-water treatment.

Disinfection of Natural Water from the Waller Creek at UT Austin

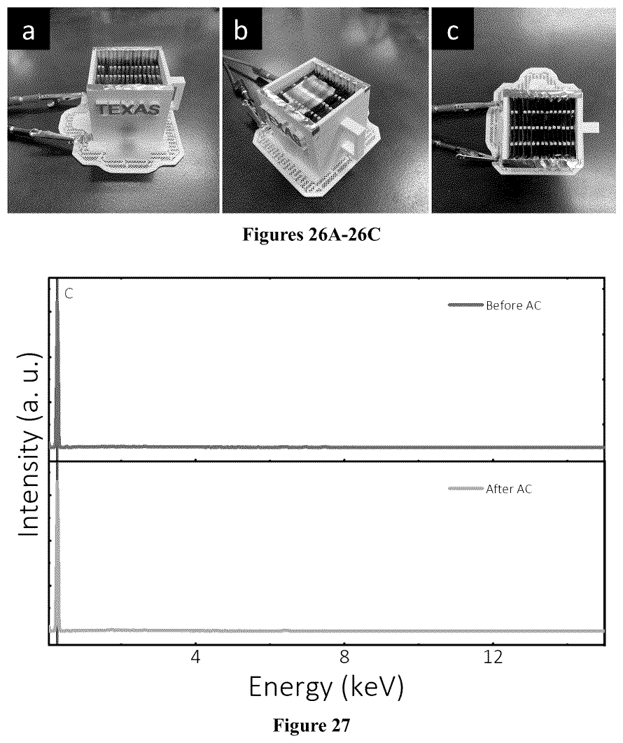

Finally, confirming the validity and applicability of the working principle and device scheme with the systematic characterization, simulation, and understanding, we develop a water-disinfection prototype powered by low-voltage AC field for natural water treatment. In the past 4 years, the E. coli pollution of Waller Creek at UT Austin indicates a high level of bacterial pollution, as shown in FIG. 25. For disinfecting water in Waller Creek, we make a portable water-disinfection cup (5×5×5 cm³) by 3D printing and integrate it with multiple DGF electrodes as a device prototype (FIG. 6F, FIGS. 26A-26C). The various bacterial colonies on the nutrient agar culture medium indicate the presence of different types of bacteria in the water sample. After the application of an AC-voltage at 10 MHz, 8V for 25 min, almost no bacterium colony can be cultured on the counting plate (FIG. 6G). This result is further confirmed by testing with commercial bacterial kits (FIG. 6H). Indeed, the designed water treatment cup can practically disinfect bacterium-contaminated fresh water in nature. In addition, no soluble mineral in river water deposits on the PDGF electrodes (FIG. 27) after the AC voltage treatment.

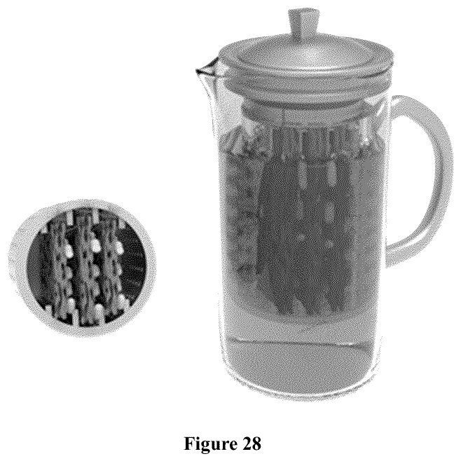

The cup is compact and can be easily produced at a low cost with the synthesis of a PDGF electrode at only $1.47 in a laboratory condition. We also designed a flow cell with a glass-pot appearance that allows for both water treatment and practical use (FIG. 28). This design enables easy filling and pouring of water after treatment. In addition, for practical applications, we suggest a general method for choosing the optimized AC frequency considering water source, different bacterium types, and energy consumption.

### CONCLUSIONS

In summary, we propose and successfully validate a meritorious scheme for bacterial disinfection and the associated materials and device prototype for future portable applications. The research is achieved by exploiting the interaction of bacterial cells with non-uniform AC electric fields created via ramified graphite foams. As low as a few volts can effectively disinfect 99.997% E. coli bacteria in bulk water. Brownian dynamics simulations further unveil the critical role of the highly ununiform AC electric field supported by the strategically designed ramified graphite foams, which directs bacterial locomotion towards the electrodes and creates high-intensity near-field zones for cell capture. This working principle is different from the reported EMI technologies, where our device operates at low AC voltages in still water without any requirement for ionic additions or forced water flows. It has a simple device scheme, desirable for POU application. Among various emerging technologies, including chlorine disinfection, UV radiation, ozonation, and solar steaming, the water-disinfection system in this report requires an energy consumption of only 435.5 J. L⁻¹. Here, the biological energy of swimming bacterial cells also, in principle, contributes to the low energy cost. The system's operation does not have restrictions in geographical location or weather condition. Combined with the simple, portable, low-cost, and robust performance, the system could find uses in extreme weather and events.

In this example, the device scheme focuses on the removal of bacteria in water. Based on the same setup, different working mechanisms could be explored to remove various types of micro/nanoobject, heavy metals, and organic contaminates. For instance, as aforediscussed, metals cannot directly deposit on electrodes by the high-frequency AC field. Nevertheless, a DC field can be explored based on the established electrodeposition methods as reported previously. In terms of micro/nanoobjects with a similar size of the bacterial cells, we expect the same DEP mechanism can be applied for their purification. In terms of organic contaminants, previous work has demonstrated their oxidization and decontamination in a DC field, the so-called electrooxidation.

Finally, we design and fabricate a prototype water disinfection cup that successfully brings natural water in the Waller Creek at UT Austin to the safe level. Overall, this research could inspire the development of a class of water disinfection systems with distinct advantages for POU applications.

### Materials and Methods

Fabrication of porous dendritic Ni foams (DNFs). The DNFs (HLDFs) were synthesized and electrodeposited successfully on commercial nickel foam substrates. Before electrodeposition, a piece of rolled commercial nickel foam (CNF, 2×4 cm², 200 μm in thickness, MTI Corporation, CA, USA) was successively washed with acetone, sulfuric acid (H₂SO₄, 3 M), and DI water to completely remove the surface oxide layer. Then, the diverging Ni—Cu microbranches were electrodeposited at −1.4 V (vs Ag/AgCl) for 150 C from an electrolyte constituted of copper sulfate (CuSO₄, 0.0025 M), nickel chloride (NiCl₂, 0.1 M), and boric acid (H₃BO₃, 0.323 M) with nickel foil (Alfa Aesar, MA, USA) working as the counter electrode on an electrochemical workstation (VersaSTAT 3, AMETEK Scientific Instruments). The electrodeposition was repeated 4 cycles with the CNF substrate rotated upside-down each time to guarantee uniform coverage of the ramified branches on the CNF substrate. Electrolyte compositions of the different porous structures: LSDF: CuSO₄, 0.001 M, NiCl₂, 0.1 M, and H₃BO₃, 0.323 M; LLDF: CuSO₄, 0.0025 M, NiCl₂, 0.025 M, and H₃BO₃, 0.323 M. The resultant DNFs were rinsed with DI water and ethanol, then dried overnight in a vacuum dryer. After completely drying, the DGFs samples were rapidly annealed for 5 min at 1000° C. in a tube furnace (Lindberg/Blue M Mini-Mite Tube Furnaces, Thermo Scientific) with a gas flow of hydrogen (H₂, 5 sccm) and nitrogen (N₂, 50 sccm) of about 440 mTorr to improve the mechanical adhesion strength between the ramified microbranches and the nickel foam substrates.

Growth of Porous Dendritic Graphite Foams (DGFs) with DNFs as Templates.

The graphite@dendritic Ni foams (GDNFs) are grown via CVD in a gas mixture of C₂H₄ and H₂ at flow rates of 10 sccm, 20 sccm, respectively, at 700° C. The reaction starts with the preparation of the surface of the dendritic Ni foam (DNFs) via reduction in H₂ gas flow (20 sccm) at 700° C. for 40 minutes to remove the surface oxides. Next, ethylene (C₂H₄, 10 sccm) is utilized as the carbon source to grow ultrathin graphite film on the DNFs catalysts with a total pressure of 400 mTorr for 15 hr. Then, the temperature is rapidly reduced to room temperature in the original growth gas mixture. GDNFs are obtained with a layer of thin graphite conformably coating on the DNFs. Free-standing DGFs, which well replicate the porously branched superstructures of the DNFs, are obtained via selectively chemical etching of the metal foam core in a FeCl₃/HCl mixture (FeCl₃/HCl=1 M/2M). The resultant ultrathin graphite foam is carefully rinsed with deionized water and isopropanol, and finally dried at 60° C. for 4 hours. Finally, the DGFs are treated with hydrophilic in nitric acid (HNO₃, 4 M) at 50° C. for 2 hours, followed by rinsing with DI water and isopropanol.

Water-disinfection device: design and fabrication. The construction of the water-disinfection device starts with the assembly of 4 pieces of GDNFs with an inter-distance of 250 μm into slots of a cuboid container (3×1×4 cm³) made by 3D printer (MakerBot Replicator 5th Generation), followed by the selective chemical etching of the Ni core in FeCl₃/HCl mixture (FeCl₃/HCl=1 M/2 M) and deionized-water washing to obtain the DNFs. Various arrangements of the DGFs are configured in both the horizontal and vertical directions of the water container (FIGS. 20A-20D). An electrically conductive copper tape is attached to one end of each piece of DNF, serving as the current collector. To protect the copper tape during the chemical etching of the Ni core of the foam, a layer of polydimethylsiloxane (PDMS) made of a mixture of base and curing agent (mass ratio of 10:1) is evenly coated on its surface followed by degassing in vacuum for 1 hour and curing at 65° C. for 2 hr.

Materials characterization. The voltage supply for water treatment is provided by a function generator (Agilent 33250A). In order to calculate the energy consumption of our water treatment device, the measurement of the voltage and current of our device is carried out with an oscilloscope (Tektronix TDS 2024B). The working circuit for the test is shown in FIG. 6D. The morphologies and microstructures of DNFs and DGFs are successively characterized by scanning electron microscopy (SEM, Hitachi S5500) equipped with energy dispersive spectroscopy (Brucker), Raman spectroscopy (customized setup with ultrasensitive CCD camera from Princeton instrument Inc.), and high-resolution transmission electron microscope (TEM, JEOL 2010F).

Bacterial characterization. Commercial Escherichia coli (E. coli) solution (Carolina biological supply) is diluted 1000 times to ˜10⁶ CFU/mL (colony forming unit) with biological-grade water (Cat. No. W4502-1L, Sigma-Aldrich). The diluted bacterial suspension is transferred to the water treatment device. During the water treatment, a constant electric voltage is applied to the DGFs electrodes via a functional generator. The characteristics of the applied electric field, i.e., AC voltage and frequency, DC voltage, and application duration are optimized to achieve excellent disinfection efficiency. Next, the treated water samples are collected with the electric voltage on. The DGFs are cleaned by large amounts of 75 vol. % alcohol and DI water and stored for the next use. The bacterial concentrations of the processed suspensions and control samples are measured by using the standard spread plating techniques: 20-g solid agar (BP1423-500, Fisher) is dissolved in 500 ml DI water in a conical flask, which is then placed into an oven at 120° C. for 2 hours to obtain the agar solution. Next, 20-mL agar solution is transferred to a petri dish with a diameter of 80 mm. The petri dish is then placed into a CO₂ incubator (MCO-17AC, SANYO) at 37° C. for 12 hours to obtain the solidified agar medium. For the bacteria culture, each water sample is serially and accurately diluted. Then, a 400 μL diluted water sample is transferred to the petri dish containing pre-solidified agar, and an L-shaped glass rod is utilized to smear the solution to spread on the agar surface. At last, the plates are transferred to a CO₂ incubator with 5.0 vol % CO₂ and cultured at 37° C. for about 20 hr. The bacterial concentration in the water sample can be calculated through the number of the bacterial colonies, dilution ratio and water volume. Note that the use CO₂ is for maintaining the pH value of the solution. It is not necessary for the culture of E. coli cells but can be needed for other types of bacterial cells. As we tested the application of the device for the removal of bacteria from Waller creek, we controlled the pH value with the standard 5% CO₂ technique.

The motions of bacterial cells on the microelectrodes are observed with an inverted optical microscope (Olympus IX 71). To determine E. coli cells captured by the DGFs electrodes with SEM imaging, after water treatment, the DGF are collected and immersed overnight in 2.5% glutaraldehyde solution (Sigma-Aldrich) at 4° C. for cell fixing. Then the samples are rinsed 3 times with 0.1 M, pH 6.6 phosphate buffer solution (Sigma-Aldrich), successively dehydrated by a gradient of ethanol/water solutions (30%, 50%, 70%, 80%, 90%, 95% and 100 wt. %, 15 min for each time), and dried in air. Bacterial tests for the treatment of natural water are performed with water testing kits (Test Assured).

### Locomotion of Bacterial Cells in Water

Background information of E. coli bacteria. It has been found that E. coli cells exhibit two modes of locomotion in fluid, i.e., linear translocation (running) and rotational motion (tumbling). A typical E. coli cell swims along a linear trajectory and then randomly rotates to another direction before continuing the translocation. Due to this unique locomotion behavior, E. coli cells propelled by rotating flagellar, exhibit random walks. The specific swimming characteristics of E. coli cells depends on the fluid's properties. The spontaneous swimming velocity of E. coli is in the range of 10-35 μm/s.

Movement behaviors of E. coli bacteria in an AC electric field. The movement characteristics of E. coli cells in an applied electric field, particularly an AC electric field, needs further investigation. The response of bacterial cells to a non-uniform AC electric field, as the fundamental principle of our bacteria capture hypothesis, determines the feasibility of the water purification strategy. To evaluate this, microelectrodes are utilized to sustain a non-uniform AC electric field with large penetration depth, under which the movement characteristics of E. coli bacterial cells are observed with an optical microscope. The induced AC dipole of a bacterial cell with complex electric permittivity results in a DEP force, which can accelerate its motion in the electric field. The microscopic images (FIGS. 8A-8D) and a real-time movie confirm the active response of E. coli cells to an applied AC electric field via a pair of parallel microelectrodes. When no electric field is applied to the microelectrodes, spontaneous random motions are observed on the E. coli cells as illustrated in FIG. 8A. While nearly all E. coli cells are aligned instantly upon the application of the AC electric field (8 V, 10 MHz) (FIG. 8B). In this AC electric field, the E. coli cells are aligned and migrate towards the edges of the microelectrodes. After applying the AC electric field for about 2 min (FIG. 8C), most of the E. coli cells are trapped at the edges of the microelectrodes, which unambiguously demonstrates the strong and rapid response of bacterial cells to the applied AC electric field. In addition, interestingly, after the removal of the AC electric field, the E. coli cells on the microelectrodes are released and resume their random motions again. (FIG. 8D). These results indicate that effective capture and release of bacterial cells can be achieved owing to the strong response of bacterial cells to a non-uniform AC field, which provides the base and validation to the reported new mechanism, design, and device for water purification reported in this example.

### Temperature Effects

Our experiments are carried out at room temperature. Multiple factors that govern bacterial removal efficiency depend on temperature, such as Brownian motion, moving speed, viability of bacterial cells. The results depend on the specificity of all these factors. For instance, we notice that deliberately increasing temperature can increase Brownian motion, however, it also consumes energy significantly due to water heating and increases device complexity. Therefore, we focus on developing a room-temperature operating device. At a low temperature (above the freezing temperature), Brownian motion should decrease, so does the bacterial mobility. Nevertheless, we believe we are still able to remove bacteria, since the device can successfully remove non-mobile bacteria, such as Shigella.

Discussion on disinfection efficiency in low AC frequencies. The disinfection efficiency increases when the AC field frequency changes from 100 Hz to 1 Hz because the working mechanism is distinct. In particular, when it reaches between 1 and 10 Hz, the range close to a DC field, many bubbles generate due to electrolysis. Since DC (or close-to-DC) electric field is not effective in capturing bacteria to the electrodes in bulk water, the observed disinfection at the close-to-DC fields should arise from a distinct mechanism from the DEP force. It can be attributed to the hydroxyl free radical by-products generated during the electrolysis that lyse bacteria.

DC voltage effect on metal electrode. At a DC or low-frequency AC voltage in solution, electrochemical reaction can occur on electrodes that partially dissolve the electrodes. For instance, we observe the damage of Au/Cr thin film electrodes at 3V (DC voltage) in deionized water. The specific voltage that can cause electrochemical etching depends on the electrochemical potential of a metal. For instance, Ni and Cu are more active and react at a lower voltage compared to that of Au. A schematic diagram is shown in FIG. 16.

Dendritic graphite offers reliable performance for bacterial disinfection. We conducted experiments using various metallic foams, including Ni, Ni/Cu dendrites, and annealed Ni/Cu dendrites, as well as graphite@ dendritic Ni foam, as we carried the question—whether metallic foams could serve for bacterial disinfection based on the same approach. The experimental results in FIGS. 17A-17B show that when using foams with metal integration, including the graphite@ dendritic foam, they release metal ions into water and introduce ionic contamination. This can be due to electrochemical etching, i.e., metals are slowly etched in the high-frequency electric field and release ions.

In contrast, the use of dendritic graphite as conductive electrodes for bacteria capture shows high functional stability as demonstrated in the experiments and does not induce such an issue.

TABLE 1
Comparison of disinfection efficiency of bacteria at
different concentrations (at 8 V/10 MHz, 25 min).

| | Bacterial concentration (CFU/mL) | | |
|---|---|---|---|
| | ~3 × 10⁷ | ~3 × 10⁶ | ~2 × 10⁵ |
| Disinfection efficiency (%) | 99.997 | 99.997 | 99.998 |
| Error bar (%) | 7.9 × 10⁻⁴ | 9.0 × 10⁻⁴ | 2.3 × 10⁻⁴ |

Disinfection efficiency of different bacterial concentrations. We conducted experiments to disinfect bacteria with concentrations from ˜3×10⁷ to ˜2×10⁵ CFU/mL. As shown below, the bacterial disinfection efficiency does not show a clear difference based on the bacterial concentration.

Calculation of energy consumption. To investigate the energy consumption of our water disinfection module (3×1×4 cm³), the current and component voltage are measured during the disinfection process (8 V, 10 MHz, 25 min). The Schematic diagram of the testing circuit is illustrated in FIG. 6D, where V₀ represents the voltage of functional generator, R₂ represents an external resistance with a known resistance value of 1500Ω, while R₁ and C₁ together represent our water disinfection device. During the test, V₀ and V₂ can be simultaneously evaluated by using an oscilloscope. V₀ is constantly adjusted that V₁=V₀−V₂=8 V. We determine that V₀=9.7 V, V₂=1.7 V. Then the energy consumption of our water purification module (W₁) can be calculated as follows:

$$φ = 2 π \cdot \frac{1}{10} = \frac{π}{5} \qquad ( 1 )$$

$$ω = 2 π \cdot f = 6.28 \times {10}^{7} Hz \qquad ( 2 )$$

$$I = \frac{{V}_{2}}{{R}_{2}} = \frac{1.7}{1500} = 1 \text{.13} \times {10}^{- 3} A \qquad ( 3 )$$

$${W}_{2} = \frac{{V}_{2}^{2}}{2 {R}_{2}} \cdot T = 1.445 J \qquad ( 4 )$$

$${W}_{0} = {\int }_{0}^{{T}_{}} {V}_{0} \cdot sin ω t \cdot I \cdot sin ( ω t + φ ) \cdot dt = 6.671 J \qquad ( 5 )$$

$${W}_{1} = {W}_{0} - {W}_{2} = 5.226 J \qquad ( 6 )$$

For 1 Litter of water for treatment.

$${W}_{1 L} = \frac{{W}_{1}}{V} = \frac{5.226 J}{0.012 L} = 435.5 J \cdot {L}^{- 1}$$

The consumption of energy is 435.5 J for treating 1 L contaminated water with our device.

Mineral deposition on electrodes in a high-frequency AC field. Theoretically, it is difficult to electrodeposit soluble mineral ions in water on an electrode with a high frequency AC voltage. It is because in a high frequency AC field, such as MHz, metal ions do not have sufficient time to diffuse through the electric double layer next to the electrode for reductive deposition before the polarity of the electric voltage has been reversed. The characteristic time of an electric double layer is on the order of ten microseconds, and the AC frequency we used is >1 MHz.

For further understanding, we conduct experiments in simulated river water with soluble minerals of 14.7 mg/L Ca²⁺, 3.0 mg/L Mg²⁺, 7.2 mg/L Na⁺, 1.4 mg/L K⁺, 19.1 mg/L HCO₃⁻, 12.0 mg/L SO₄²⁻—, 27.3 mg/L Cl⁻; the composition is similar to that of natural rivers. We applied 20 Vpp, 10 MHz for 25 min to PGDF electrode and characterized the electrodes afterward. The EDS characterizations show no evidence of metal deposition on the surface of the electrodes in FIG. 27.

TABLE 2
Calculation of the cost of making one piece of DNF.

| | | | Consumption per | | |
|---|---|---|---|---|---|
| Materials | Price | | sample (2 × 4 cm²) | | Cost ($) |
| NiCl₂ | ~$145, 2 | kg | 3.8 | g | 0.276 |
| CuSO₄ | ~$66, 1 | kg | 0.1 | g | 0.007 |
| H₃BO₃ | ~$43, 2 | kg | 3.2 | g | 0.069 |
| C₂H₄ | ~$830, 13.6 | kg | 10.6 | g | 0.216 |
| H₂ | ~$65, 0.676 | kg | 1.5 | g | 0.049 |
| FeCl₃ | ~$37, 0.5 | kg | 4.0 | g | 0.296 |
| HCl | ~$30, 2.5 | L | 2.5 | mL | 0.030 |
| HNO₃ | ~$30, 2.5 | L | 1.9 | mL | 0.021 |
| Ni Foam | ~$188, 3000 | cm² | 8 | cm² | 0.501 |

| | |
|---|---|
| Sum | 1.47 |

Methods for Determining the Optimized AC frequency. Our experimental results show different types of bacteria can have different optimized AC frequencies for their removal. For the demonstrated E. coli and shigella, two common bacterial species found in freshwater that cause human diseases, both can be removed with excellent efficiencies across a broad AC frequency range, and particularly at 10 MHz (FIG. 3C and FIG. 21A). Therefore, when treating water from Waller creek (FIGS. 6G, 6H), we employed 10 MHz with the understanding that most bacterial cells (mobile, such as E. coli; nonmobile, such as shigella) share similar compositions and structures. Indeed, we successfully disinfected water from Waller creek, indicating 10 MHz is an effective frequency for such water. Therefore, for people, such as those travelling in the wild, who need drinkable water using natural freshwater as the source, but do not know the bacterial types, we recommend 10 MHz as the testing frequency.

For people who would like to regularly access drinkable water via disinfecting a known freshwater body in nature, we recommend the following general approach for an optimized bacterial disinfection efficiency at a given energy cost:
1. Determine the bacterial species and their concentrations in water.
2. Determine disinfection efficiency versus AC frequency for each type of disease-causing bacterium.
3. Based on the results obtained in 2, determine the optimized AC frequency in terms of removal efficiency for each type of bacterium.
4. According to the concentration and desired disinfection limit of a bacterium species, determine the electric voltage at its optimized AC frequency so that the same amount of time is used for removing different bacterium species in the water body.
5. Create a synthetic electric voltage by adding all the AC frequencies with the corresponding voltages determined in 4. This step is taken with the understanding that electric effects based on different AC frequencies for micro/nanoparticle manipulation can be directly superimposed.
6. Apply the obtained synthetic electric voltage for water disinfection.

We note the above provides a general approach with the consideration that the optimized AC frequencies are unique for each type of bacterium. When multiple bacterial species share the same optimized AC frequency or exhibit significant removal efficiency at the optimized frequency of another, a detailed mathematic analysis should be conducted for determining the synthetic waveform for efficiency optimization at a given energy consumption.

Brownian Dynamics Simulation of the Bacteria Purification. The distinct experimental results of the purification efficiency of motile E. coli and non-motile bacteria Shigella (FIGS. 21A-21B, 22A-22D) indicate that the mobility of the bacteria is also a vital parameter that governs the purification process. To investigate the contribution of DEP forces, bacteria's locomotion, and the diffusion of bacteria during the purification process, we built a 1D Brownian dynamics model. In the simulation domain, the electric field distribution is calculated via COMSOL.

First, 100000 bacteria are seeded uniformly in the simulation domain between two electrodes. Each bacterium cell is then assigned with a constant locomotion speed and direction. For E. coli, the locomotion speeds follow a Gaussian distribution with μ=5.1 μm/s and σ=2.2 μm/s. The motion of each bacteria is governed by the following equation of motion:

$$\dot{X} ( t ) = \frac{D}{{k}_{B} T} {F}_{D E P} ( X ) + {V}_{loco} + \sqrt{2 D} R ( t )$$

where X(t) is the coordinate of the bacteria, D is the diffusivity of bacteria, F_{DEP}(X) is dielectrophoresis force, V_{loco} is the locomotion velocity of the E. coli and R(t) is a delta-correlated stationary Gaussian process that follows: [symbol] R(t) [symbol] =0 and [symbol] R(t)R(t′) [symbol] =δ(t−t′). The time step dt is selected to be much larger than the relaxation time of bacteria's Brownian motion, which guarantees the simulation is overdamped.

In the simulation, we are able to turn the diffusion, locomotion, and the DEP force on and off. Initially, all bacteria are assigned an untrapped state. Once a bacterium reaches one of the electrodes, which are also the simulation domain boundaries, they will be defined as trapped and no longer able to move. We consider the DEP force near the highly branched electrodes attach the bacteria cells once contacting them as suggested by our experimental studies in FIGS. 6A, 6B.

The effect of motility is studied in electrodes with a gap of 250 um under diffusion, locomotion, and the DEP force as shown in FIGS. 5A-5E. The result indicates that as the motility increases, the capture efficiency monotonically increases, indicating that the locomotion of bacteria towards the electrodes greatly facilitates the trapping of bacteria in addition to the DEP. To better understand the contribution from diffusion, locomotion, and DEP, we conduct a series of simulations with only one of the three processes being activated. As shown in FIG. 5A, the locomotion turns out to be the most significant parameter among the three, where the purple curve with only activated locomotion is highly close to the blue curve with all three processes activated. On the other hand, the other two curves with only diffusion and DEP activation, respectively, show a rather low capture efficiency over 25 minutes. The location distributions of untrapped bacteria from the above simulation are shown in FIGS. 5C-5E. When locomotion is activated, there are very few bacteria untrapped, and the distribution is quite uniform between the two electrodes. When the DEP force is activated, the regions near the two electrodes have low bacterial concentrations. However, the bacteria concentration remains unchanged at regions that are roughly 50 μm away from the electrodes. Similar distribution has been found when only the diffusion is activated. The complete parameters used for Brownian Dynamics are provided as Table 3.

TABLE 3
Parameters for Simulation

| Parameters | Value | |
|---|---|---|
| Number of bacteria (N) | 100000 | |
| semi major axis of bacteria (a) | 1 | μm |
| semi minor axis of bacteria (b) | 0.35 | μm |
| water viscosity (η) | 0.89 | mPa s |
| Drag coefficient of bacteria along the major | 8.2 × 10⁻⁹N | s m⁻¹ |
| axis (γ) | | |
| Temperature (T) | 300 | K |
| Averaged polarizability of the bacteria along | 4N | V m C⁻¹ |
| major axis (α) | | |
| E-coli locomotion velocity distribution (V_{loco}) | μ = 5.12 μm s⁻¹ | |
| | σ = 2.17 μm s⁻¹ | |
| Time step (dt) | 0.06 | s |

According to the above simulation results, we can provide qualitative understanding in distinguishing the contribution from these three processes. The locomotion of bacteria is the dominating factor for the bacteria removal. However, it is essential to have the AC electric field to keep the bacteria's locomotion direction towards one of the electrodes. Otherwise, the bacteria would tumble and steer to other directions, and thus lowering capture efficiency. In our simulation we do not consider bacteria tumbling because as shown in videos, we do not observe any tumbling of the bacterial cells under the electric field. The electro-alignment torque is strong enough to prevent E. coli tumbling and confine their locomotion direction. Even if there is tumbling that a bacterium reorients its moving direction, the cell will just swim towards another electrode and get captured.

The DEP force is another vital process for bacteria removal, yet it is most effective in the vicinity of the electrode via short-range interaction since the field gradient decays rapidly with the distance from the surface of the dendritic microelectrodes. For those bacteria beyond this DEP trapping region, they cannot be trapped until they either swim into or passively diffuse into the trapping regions. Moreover, the passive diffusion requires a long duration and thus results in low removal efficiency for non-motile bacteria. Note the simulation results are obtained from 1D simulation. It can provide qualitatively understanding to the manipulation and disinfection mechanism, where the experimental results are obtained from 3D manipulation and highly branched porous electrodes.

Other electrokinetic effects, such as electrophoretic and electroosmotic efforts, exist in DC field and low-frequency AC field, such as 10 kHz and below in solution of low conductivity; electrothermal flow exhibits effects in high ionic solutions The diminishing of such effects in high AC frequency and medium of low conductivity has been well determined. Therefore, in the simulation, we focused on phenomena that are present in high-frequency AC field, the DEP force and electro-alignment. The efforts unveiled the contribution of electro-alignment in the far-from-electrode region for the aligned swimming of bacteria toward electrodes, and DEP force in the near-electrode region for the capture by the electrodes.

### REFERENCES

(1) Shannon, M. A.; Bohn, P. W.; Elimelech, M.; Georgiadis, J. G.; Marinas, B. J.; Mayes, A. M. Science and Technology for Water Purification in the Corning Decades. Nature 2008, 452 (7185), 301-310. https://doi.org/10.1038/natureO6599.
(2) Mullin, M. The Effects of Drinking Water Service Fragmentation on Drought-Related Water Security. Science 2020, 368 (6488), 274-277. https://doi.org/10.1126/science.aba7353.
(3) Werber, J. R.; Osuji, C. O.; Elimelech, M. Materials for Next-Generation Desalination and Water Purification Membranes. Nat. Rev. Mater. 2016, 1 (5), 1-15. https://doi.org/10.1038/natrevmats.2016.18.
(4) Amrose, S.; Burt, Z.; Ray, I. Safe Drinking Water for Low-Income Regions. Annu. Rev. Environ. Resour. 2015, 40 (1), 203-231. https://doi.org/10.1146/annurev-environ-031411-091819.
(5) Sadoff, C. W.; Borgomeo, E.; Uhlenbrook, S. Rethinking Water for SDG 6. Nat. Sustain. 2020, 3 (5), 346-347. https://doi.org/10.1038/s41893-020-0530-9.
(6) Guidelines for Drinking-Water Quality: Fourth Edition Incorporating the First and Second Addenda; WHO Guidelines Approved by the Guidelines Review Committee; World Health Organization: Geneva, 2022.
(7) Schwarzenbach, R. P.; Escher, B. I.; Fenner, K.; Hofstetter, T. B.; Johnson, C. A.; von Gunten, U.; Wehrli, B. The Challenge of Micropollutants in Aquatic Systems. Science 2006, 313 (5790), 1072-1077. https://doi.org/10.1126/science. 1127291.
(8) Zhang, M.; Xie, X.; Tang, M.; Criddle, C. S.; Cui, Y.; Wang, S. X. Magnetically Ultraresponsive Nanoscavengers for Next-Generation Water Purification Systems. Nat. Commun. 2013, 4 (1), 1866. https://doi.org/10.1038/ncomms2892.
(9) Cohen-Tanugi, D.; McGovern, R. K.; Dave, S. H.; Lienhard, J. H.; Grossman, J. C. Quantifying the Potential of Ultra-Permeable Membranes for Water Desalination. Energy Environ. Sci. 2014, 7 (3), 1134-1141. https://doi.org/10.1039/C3EE43221A.
(10) Van der Bruggen, B.; Vandecasteele, C. Distillation vs. Membrane Filtration: Overview of Process Evolutions in Seawater Desalination. Desalination 2002, 143 (3), 207-218. https://doi.org/10.1016/S0011-9164(02)00259-X.
(11) Wenten, I. G.; Khoiruddin. Reverse Osmosis Applications: Prospect and Challenges. Desalination 2016, 391, 112-125. https://doi.org/10.1016/j.desal.2015.12.011.
(12) Li, W.; Li, Z.; Bertelsmann, K.; Fan, D. E. Portable Low-Pressure Solar Steaming-Collection Unisystem with Polypyrrole Origamis. Adv. Mater. 2019, 31 (29), 1900720. https://doi.org/10.1002/adma.201900720.
(13) Tao, P.; Ni, G.; Song, C.; Shang, W.; Wu, J.; Zhu, J.; Chen, G.; Deng, T. Solar-Driven Interfacial Evaporation. Nat. Energy 2018, 3 (12), 1031-1041. https://doi.org/10.1038/s41560-018-0260-7.
(14) Min, X.; Zhu, B.; Li, B.; Li, J.; Zhu, J. Interfacial Solar Vapor Generation: Materials and Structural Design. Acc. Mater. Res. 2021, 2 (4), 198-209. https://doi.org/10.1021/accountsmr.0c00104.
(15) Chuang, Y.-H.; Mitch, W. A. Effect of Ozonation and Biological Activated Carbon Treatment of Wastewater Effluents on Formation of N-Nitrosamines and Halogenated Disinfection Byproducts. Environ. Sci. Technol. 2017, 51 (4), 2329-2338. https://doi.org/10.1021/acs.est.6b04693.
(16) Szczuka, A.; Parker, K. M.; Harvey, C.; Hayes, E.; Vengosh, A.; Mitch, W. A. Regulated and Unregulated Halogenated Disinfection Byproduct Formation from Chlorination of Saline Groundwater. Water Res. 2017, 122, 633-644. https://doi.org/10.1016/j.watres.2017.06.028.
(17) Sun, M.; Wang, X.; Winter, L. R.; Zhao, Y.; Ma, W.; Hedtke, T.; Kim, J.-H.; Elimelech, M. Electrified Membranes for Water Treatment Applications. ACS EST Eng. 2021, 1 (4), 725-752. https://doi.org/10.1021/acsestengg.1c00015.
(18) Guo, L.; Ding, K.; Rockne, K.; Duran, M.; Chaplin, B. P. Bacteria Inactivation at a Sub-Stoichiometric Titanium Dioxide Reactive Electrochemical Membrane. J. Hazard. Mater. 2016, 319, 137-146. https://doi.org/10.1016/j.jhazmat.2016.05.051.
(19) Kotnik, T.; Frey, W.; Sack, M.; Haberl Meglič, S.; Peterka, M.; Miklavčič, D. Electroporation-Based Applications in Biotechnology. Trends Biotechnol. 2015, 33 (8), 480-488. https://doi.org/10.1016/j.tibtech.2015.06.002.
(20) Schoenbach, K. H.; Joshi, R. P.; Stark, R. H.; Dobbs, F. C.; Beebe, S. J. Bacterial Decontamination of Liquids with Pulsed Electric Fields. IEEE Trans. Dielectr. Electr. Insul. 2000, 7 (5), 637-645. https://doi.org/10.1109/94.879359.
(21) Gehl, J. Electroporation: Theory and Methods, Perspectives for Drug Delivery, Gene Therapy and Research. Acta Physiol. Scand. 2003, 177 (4), 437-447. https://doi.org/10.1046/j.1365-201X.2003.01093.x.
(22) Yang, C.; Wen, L.; Li, Y.; Li, X. Fabrication of 5n02-Sb Reactive Membrane Electrodes for High-Efficiency Electrochemical Inactivation of Bacteria and Viruses in Water. Chem. Eng. J. 2022, 446, 137327. https://doi.org/10.1016/j.cej.2022.137327.
(23) Mahmoud, M.; El-Liethy, M. A. Three-Dimensional, Flow-through Silver-Magnetite Nanocomposite-Modified Reactive Electrochemical System with Slow Silver Ions Release for Efficient Bacterial Disinfection of Sewage. J. Environ. Chem. Eng. 2022, 10 (1), 106985. https://doi.org/10.1016/j.jece.2021.106985.
(24) Liang, S.; Lin, H.; Habteselassie, M.; Huang, Q. Electrochemical Inactivation of Bacteria with a Titanium Sub-Oxide Reactive Membrane. Water Res. 2018, 145, 172-180. https://doi.org/10.1016/j.watres.2018.08.010.
(25) Wang, C.; Yue, L.; Wang, S.; Pu, Y.; Zhang, X.; Hao, X.; Wang, W.; Chen, S. Role of Electric Field and Reactive Oxygen Species in Enhancing Antibacterial Activity: A Case Study of 3D Cu Foam Electrode with Branched CuO—ZnO NWs. J. Phys. Chem. C 2018, 122 (46), 26454-26463. https://doi.org/10.1021/acs.jpcc.8b08232.
(26) Huo, Z.-Y.; Zhou, J.-F.; Wu, Y.; Wu, Y.-H.; Liu, H.; Liu, N.; Hu, H.-Y.; Xie, X. A Cu₃P Nanowire Enabling High-Efficiency, Reliable, and Energy-Efficient Low-Voltage Electroporation-Inactivation of Pathogens in Water. J. Mater. Chem. A 2018, 6 (39), 18813-18820. https://doi.org/10.1039/C8TA06304D.
(27) Huo, Z.-Y.; Xie, X.; Yu, T.; Lu, Y.; Feng, C.; Hu, H.-Y. Nanowire-Modified Three-Dimensional Electrode Enabling Low-Voltage Electroporation for Water Disinfection. Environ. Sci. Technol. 2016, 50 (14), 7641-7649. https://doi.org/10.1021/acs.est.6b01050.
(28) Schoen, D. T.; Schoen, A. P.; Hu, L.; Kim, H. S.; Heilshorn, S. C.; Cui, Y. High Speed Water Sterilization Using One-Dimensional Nanostructures. Nano Lett. 2010, 10 (9), 3628-3632. https://doi.org/10.1021/n1101944e.
(29) Huo, Z.-Y.; Li, G.-Q.; Yu, T.; Lu, Y.; Sun, H.; Wu, Y.-H.; Yu, C.; Xie, X.; Hu, H.-Y. Impact of Water Quality Parameters on Bacteria Inactivation by Low-Voltage Electroporation: Mechanism and Control. Environ. Sci. Water Res. Technol. 2018, 4 (6), 872-881. https://doi.org/10.1039/C8EW00041G.
(30) Huo, Z.-Y.; Liu, H.; Wang, W.-L.; Wang, Y.-H.; Wu, Y.-H.; Xie, X.; Hu, H.-Y. Low-Voltage Alternating Current Powered Polydopamine-Protected Copper Phosphide Nanowire for Electroporation-Disinfection in Water. J. Mater. Chem. A 2019, 7 (13), 7347-7354. https://doi.org/10.1039/C8TA10942G.
(31) Yue, L.; Chen, S.; Wang, S.; Wang, C.; Hao, X.; Cheng, Y. F. Water Disinfection Using Ag Nanoparticle-CuO Nanowire Co-Modified 3D Copper Foam Nanocomposites in High Flow under Low Voltages. Environ. Sci. Nano 2019, 6 (9), 2801-2809. https://doi.org/10.1039/C9EN00455F.
(32) Huang, Y.; Guo, J.; Li, Y.; Li, H.; Fan, D. E. 2D-Material-Integrated Micromachines: Competing Propulsion Strategy and Enhanced Bacterial Disinfection. Adv. Mater. 2022, 34 (30), 2203082. https://doi.org/10.1002/adma.202203082.
(33) Zhang, Z.; Wang, L.; Chan, T. K. F.; Chen, Z.; Ip, M.; Chan, P. K. S.; Sung, J. J. Y.; Zhang, L. Micro-/Nanorobots in Antimicrobial Applications: Recent Progress, Challenges, and Opportunities. Adv. Healthc. Mater. 2022, 11 (6), 2101991. https://doi.org/10.1002/adhm.202101991.
(34) Guo, J.; Liang, Z.; Huang, Y.; Kim, K.; Vandeventer, P.; Fan, D. Acceleration of Biomolecule Enrichment and Detection with Rotationally Motorized Opto-Plasmonic Microsensors and the Working Mechanism. ACS Nano 2020, 14 (11), 15204-15215. https://doi.org/10.1021/acsnano.0c05429.
(35) Ratna, R. V. Economic Analysis of Health Impacts in Developing Countries⋆. In Encyclopedia of Environmental Health (Second Edition); Nriagu, J., Ed.; Elsevier: Oxford, 2019; pp 221-230. https://doi.org/10.1016/B978-0-12-409548-9.10939—X.
(36) Cisneros, B. J. 4.06—Safe Sanitation in Low Economic Development Areas. In Treatise on Water Science; Wilderer, P., Ed.; Elsevier: Oxford, 2011; pp 147-200. https://doi.org/10.1016/B978-0-444-53199-5.00082-8.
(37) Herman, J. S.; Gellasch, C. A. Geohydrology: Hydrogeochemistry. In Encyclopedia of Geology (Second Edition); Alderton, D., Elias, S. A., Eds.; Academic Press: Oxford, 2021; pp 416-425. https://doi.org/10.1016/B978-0-12-409548-9.12504-7.
(38) Liang, Z.; Teal, D.; Fan, D. (Emma). Light Programmable Micro/Nanomotors with Optically Tunable in-Phase Electric Polarization. Nat. Commun. 2019, 10 (1), 5275. https://doi.org/10.1038/s41467-019-13255-6.
(39) Pohl, H. A. Dielectrophoresis: The Behavior of Neutral Matter in Nonuniform Electric Fields; Cambridge monographs on physics; Cambridge University Press: Cambridge; 1978.
(40) Morgan, H.; Green, N. G. AC Electrokinetics Colloids and Nanoparticles; Microtechnologies and microsystems series; Research Studies Press; Institute of Physics Pub.; Distribution, North America, AIDC: Baldock, Hertfordshire, England, Philadelphia, Pa., Williston, VT.
(41) Liang, Z.; Fan, D. (Emma). Versatile Microparticle Propulsion System by Light-Guided Dielectrophoresis: Proposed Method and Theoretical Calculation. J. Appl. Phys. 2021, 130 (5), 054902. https://doi.org/10.1063/5.0052117.
(42) Fernádez-Morales, F. H.; Duarte, J. E.; Samitier-Martí, J. Bacterial Handling under the Influence of Non-Uniform Electric Fields: Dielectrophoretic and Electrohydrodynamic Effects. An. Acad. Bras. Ciênc. 2008, 80, 627-638. https://doi.org/10.1590/S0001-37652008000400004.
(43) Park, S.; Zhang, Y.; Wang, T.-H.; Yang, S. Continuous Dielectrophoretic Bacterial Separation and Concentration from Physiological Media of High Conductivity. Lab. Chip 2011, 11 (17), 2893-2900. https://doi.org/10.1039/C1LC20307J.
(44) Li, W.; Tekell, M. C.; Liu, C.; Hethcock, J. A.; Fan, D. Flexible All-Solid-State Supercapacitors of High Areal Capacitance Enabled by Porous Graphite Foams with Diverging Microtubes. Adv. Funct. Mater. 2018, 28 (29), 1800601. https://doi.org/10.1002/adfm.201800601.
(45) Li, W.; Xu, X.; Liu, C.; Tekell, M. C.; Ning, J.; Guo, J.; Zhang, J.; Fan, D. Ultralight and Binder-Free All-Solid-State Flexible Supercapacitors for Powering Wearable Strain Sensors. Adv. Funct. Mater. 2017, 27 (39), 1702738. https://doi.org/10.1002/adfm.201702738.
(46) Chen, Z.; Ren, W.; Gao, L.; Liu, B.; Pei, S.; Cheng, H.-M. Three-Dimensional Flexible and Conductive Interconnected Graphene Networks Grown by Chemical Vapour Deposition. Nat. Mater. 2011, 10 (6), 424-428. https://doi.org/10.1038/nmat3001.
(47) Hu, G.; Xu, C.; Sun, Z.; Wang, S.; Cheng, H.-M.; Li, F.; Ren, W. 3D Graphene-Foam-Reduced-Graphene-Oxide Hybrid Nested Hierarchical Networks for High-Performance Li—S Batteries. Adv. Mater. 2016, 28 (8), 1603-1609. https://doi.org/10.1002/adma.201504765.
(48) Li, X.; Cai, W.; An, J.; Kim, S.; Nah, J.; Yang, D.; Piner, R.; Velamakanni, A.; Jung, I.; Tutuc, E.; Banerjee, S. K.; Colombo, L.; Ruoff, R. S. Large-Area Synthesis of High-Quality and Uniform Graphene Films on Copper Foils. Science 2009, 324 (5932), 1312-1314. https://doi.org/10.1126/science. 1171245.
(49) Li, X.; Colombo, L.; Ruoff, R. S. Synthesis of Graphene Films on Copper Foils by Chemical Vapor Deposition. Adv. Mater. 2016, 28 (29), 6247-6252. https://doi.org/10.1002/adma.201504760.
(50) Guo, J.; Chan, A.; Li, W.; Fan, D. L. Kirkendall Effect in Creating Three-Dimensional Metal Catalysts for Hierarchically Porous Ultrathin Graphite with Unique Properties. Chem. Mater. 2017, 29 (11), 4991-4998. https://doi.org/10.1021/acs.chemmater.7b01518.
(51) Shahini, M.; Yeow, J. T. W. Cell Electroporation by CNT-Featured Microfluidic Chip. Lab. Chip 2013, 13 (13), 2585-2590. https://doi.org/10.1039/C3LC00014A.
(52) Sanchis, A.; Brown, A. P.; Sancho, M.; Martínez, G.; Sebastián, J. L.; Munoz, S.; Miranda, J. M. Dielectric Characterization of Bacterial Cells Using Dielectrophoresis. Bioelectromagnetics 2007, 28 (5), 393-401. https://doi.org/10.1002/bem.20317.
(53) Valero, A.; Braschler, T.; Renaud, P. A Unified Approach to Dielectric Single Cell Analysis: Impedance and Dielectrophoretic Force Spectroscopy. Lab. Chip 2010, 10 (17), 2216-2225. https://doi.org/10.1039/C003982A.
(54) Hoettges, K. F. Dielectrophoresis as a Cell Characterisation Tool. In Microengineering in Biotechnology; Hughes, M. P., Hoettges, K. F., Eds.; Methods in Molecular Biology; Humana Press: Totowa, NJ, 2010; pp 183-198. https://doi.org/10.1007/978-1-60327-106-6_8.
(55) Afshar, S.; Salimi, E.; Braasch, K.; Butler, M.; Thomson, D. J.; Bridges, G. E. Multi-Frequency DEP Cytometer Employing a Microwave Sensor for Dielectric Analysis of Single Cells. IEEE Trans. Microw. Theory Tech. 2016, 64 (3), 991-998. https://doi.org/10.1109/TMTT.2016.2518178.
(56) Huang, E.; White, T.; Wang, B.; Shi, H.; Liu, J. Disinfection of Escherichia Coli by a Reactive Electrochemical Membrane System Involving Activated Carbon Fiber Cloth (ACFC). Water 2019, 11 (3), 430. https://doi.org/10.3390/w11030430.
(57) Masliyah, J.; Bhattacharjee, S. Fundamental Transport Equations. In Electrokinetic and Colloid Transport Phenomena; John Wiley & Sons, Ltd: Hoboken, N.J, 2006; pp 179-220. https://doi.org/10.1002/0471799742.ch6.
(58) Pethig, R. R. Dielectrophoresis: Theory, Methodology and Biological Applications; John Wiley & Sons: Hoboken, NJ, 2017.
(59) Li, J.; Du, M.; Lv, G.; Zhou, L.; Li, X.; Bertoluzzi, L.; Liu, C.; Zhu, S.; Zhu, J. Interfacial Solar Steam Generation Enables Fast-Responsive, Energy-Efficient, and Low-Cost Off-Grid Sterilization. Adv. Mater. 2018, 30 (49), 1805159. https://doi.org/10.1002/adma.201805159.
(60) Peng, B.; Gao, Y.; Lyu, Q.; Xie, Z.; Li, M.; Zhang, L.; Zhu, J. Cationic Photothermal Hydrogels with Bacteria-Inhibiting Capability for Freshwater Production via Solar-Driven Steam Generation. ACS Appl. Mater. Interfaces 2021, 13 (31), 37724-37733. https://doi.org/10.1021/acsami.1c10854.
(61) Li, H.; Zhu, W.; Li, M.; Li, Y.; Kwok, R. T. K.; Lam, J. W. Y.; Wang, L.; Wang, D.; Tang, B. Z. Side Area-Assisted 3D Evaporator with Antibiofouling Function for Ultra-Efficient Solar Steam Generation. Adv. Mater. 2021, 33 (36), 2102258. https://doi.org/10.1002/adma.202102258.
(62) Hashim, K. S.; Ali, S. S. M.; AlRifaie, J. K.; Kot, P.; Shaw, A.; Al Khaddar, R.; Idowu, I.; Gkantou, M. Escherichia Coli Inactivation Using a Hybrid Ultrasonic-Electrocoagulation Reactor. Chemosphere 2020, 247, 125868. https://doi.org/10.1016/j.chemosphere. 2020.125868.
(63) Amabilis-Sosa, L. E.; Vázquez-López, M.; Rojas, J. L. G.; Roé-Sosa, A.; Moeller-Chávez, G. E. Efficient Bacteria Inactivation by Ultrasound in Municipal Wastewater. Environments 2018, 5 (4), 47. https://doi.org/10.3390/environments5040047.
(64) Malvestiti, J. A.; Cruz-Alcalde, A.; López-Vinent, N.; Dantas, R. F.; Sans, C. Catalytic Ozonation by Metal Ions for Municipal Wastewater Disinfection and Simultaneous Micropollutants Removal. Appl. Catal. B Environ. 2019, 259, 118104. https://doi.org/10.1016/j.apcatb.2019.118104.
(65) Gomes, J.; Frasson, D.; Quinta-Ferreira, R. M.; Matos, A.; Martins, R. C. Removal of Enteric Pathogens from Real Wastewater Using Single and Catalytic Ozonation. Water 2019, 11 (1), 127. https://doi.org/10.3390/w11010127.
(66) Chen, Y.; Duan, X.; Zhou, X.; Wang, R.; Wang, S.; Ren, N.; Ho, S.-H. Advanced Oxidation Processes for Water Disinfection: Features, Mechanisms and Prospects. Chem. Eng. J. 2021, 409, 128207. https://doi.org/10.1016/j.cej.2020.128207.
(67) Pronk, W.; Ding, A.; Morgenroth, E.; Derlon, N.; Desmond, P.; Burkhardt, M.; Wu, B.; Fane, A. G. Gravity-Driven Membrane Filtration for Water and Wastewater Treatment: A Review. Water Res. 2019, 149, 553-565. https://doi.org/10.1016/j.watres.2018.11.062.
(68) Yang, J.; Monnot, M.; Ercolei, L.; Moulin, P. Membrane-Based Processes Used in Municipal Wastewater Treatment for Water Reuse: State-Of-The-Art and Performance Analysis. Membranes 2020, 10 (6), 131. https://doi.org/10.3390/membranes 10060131.
(69) Joss, A.; Siegrist, H.; Ternes, T. A. Are We about to Upgrade Wastewater Treatment for Removing Organic Micropollutants?Water Sci. Technol. 2008, 57 (2), 251-255. https://doi.org/10.2166/wst.2008.825.
(70) Nyangaresi, P. O.; Qin, Y.; Chen, G.; Zhang, B.; Lu, Y.; Shen, L. Comparison of UV-LED Photolytic and UV-LED/TiO2 Photocatalytic Disinfection for Escherichia Coli in Water. Catal. Today 2019, 335, 200-207. https://doi.org/10.1016/j.cattod.2018.11.015.
(71) Wan, Q.; Cao, R.; Wen, G.; Xu, X.; Xia, Y.; Wu, G.; Li, Y.; Wang, J.; Xu, H.; Lin, Y.; Huang, T. Efficacy of UV-LED Based Advanced Disinfection Processes in the Inactivation of Waterborne Fungal Spores: Kinetics, Photoreactivation, Mechanism and Energy Requirements. Sci. Total Environ. 2022, 803, 150107. https://doi.org/10.1016/j.scitotenv.2021.150107.
(72) Nyangaresi, P. O.; Qin, Y.; Chen, G.; Zhang, B.; Lu, Y.; Shen, L. Effects of Single and Combined UV-LEDs on Inactivation and Subsequent Reactivation of E. Coli in Water Disinfection. Water Res. 2018, 147, 331-341. https://doi.org/10.1016/j.watres.2018.10.014.
(73) Li, X.; Cai, M.; Wang, L.; Niu, F.; Yang, D.; Zhang, G. Evaluation Survey of Microbial Disinfection Methods in UV-LED Water Treatment Systems. Sci. Total Environ. 2019, 659, 1415-1427. https://doi.org/10.1016/j.scitotenv.2018.12.344.
(74) Wang, Y.; Li, A.; Cui, C. Remediation of Heavy Metal-Contaminated Soils by Electrokinetic Technology: Mechanisms and Applicability. Chemosphere 2021, 265, 129071. https://doi.org/10.1016/j.chemosphere.2020.129071.
(75) Rajendran, S.; Priya, T. A. K.; Khoo, K. S.; Hoang, T. K. A.; Ng, H.-S.; Munawaroh, H. S. H.; Karaman, C.; Orooji, Y.; Show, P. L. A Critical Review on Various Remediation Approaches for Heavy Metal Contaminants Removal from Contaminated Soils. Chemosphere 2022, 287, 132369. https://doi.org/10.1016/j.chemosphere. 2021.132369.
(76) Acar, Y. B.; Gale, R. J.; Alshawabkeh, A. N.; Marks, R. E.; Puppala, S.; Bricka, M.; Parker, R. Electrokinetic Remediation: Basics and Technology Status. J. Hazard. Mater. 1995, 40 (2), 117-137. https://doi.org/10.1016/0304-3894(94)00066-P.
(77) Martinez-Huitle, C. A.; Panizza, M. Electrochemical Oxidation of Organic Pollutants for Wastewater Treatment. Curr. Opin. Electrochem. 2018, 11, 62-71. https://doi.org/10.1016/j.coelec.2018.07.010

### ADDITIONAL REFERENCES

(1) Kumar, M. S.; Philominathan, P. The Physics of Flagellar Motion of E. Coli during Chemotaxis. Biophys Rev 2009, 2 (1), 13-20. https://doi.org/10.1007/s12551-009-0024-5.
(2) Fernádez-Morales, F. H.; Duarte, J. E.; Samitier-Martí, J. Bacterial Handling under the Influence of Non-Uniform Electric Fields: Dielectrophoretic and Electrohydrodynamic Effects. An. Acad. Bras. Ciênc. 2008, 80, 627-638. https://doi.org/10.1590/S0001-37652008000400004.
(3) Park, S.; Zhang, Y.; Wang, T.-H.; Yang, S. Continuous Dielectrophoretic Bacterial Separation and Concentration from Physiological Media of High Conductivity. Lab on a Chip 2011, 11 (17), 2893-2900. https://doi.org/10.1039/C1LC20307J.
(4) Yang, C.; Wen, L.; Li, Y.; Li, X. Fabrication of 5n02-Sb Reactive Membrane Electrodes for High-Efficiency Electrochemical Inactivation of Bacteria and Viruses in Water. Chemical Engineering Journal 2022, 446, 137327. https://doi.org/10.1016/j.cej.2022.137327.
(5) Huo, Z.-Y.; Winter, L. R.; Wang, X.-X.; Du, Y.; Wu, Y.-H.; Hubner, U.; Hu, H.-Y.; Elimelech, M. Synergistic Nanowire-Enhanced Electroporation and Electrochlorination for Highly Efficient Water Disinfection. Environ. Sci. Technol. 2022, 56 (15), 10925-10934. https://doi.org/10.1021/acs.est.2c01793.
(6) Mahmoud, M.; El-Liethy, M. A. Three-Dimensional, Flow-through Silver-Magnetite Nanocomposite-Modified Reactive Electrochemical System with Slow Silver Ions Release for Efficient Bacterial Disinfection of Sewage. Journal of Environmental Chemical Engineering 2022, 10 (1), 106985. https://doi.org/10.1016/j.jece.2021.106985.
(7) Norra, G.-F.; Baptista-Pires, L.; Cuervo Lumbaque, E.; Borrego, C. M.; Radjenovic, J. Chlorine-Free Electrochemical Disinfection Using Graphene Sponge Electrodes. Chemical Engineering Journal 2022, 430, 132772. https://doi.org/10.1016/j.cej.2021.132772.
(8) Wang, S.; Dong, L.; Zhang, M.; Cheng, F.; Chen, S. N-Doped Carbon-Coated Cu₂O Nanowire Arrays on Copper Foam for Rapid and Stable Water Disinfection. Journal of Colloid and Interface Science 2022, 625, 761-773. https://doi.org/10.1016/j.jcis.2022.06.054.
(9) Ni, X.-Y.; Wu, Y.-H.; Liu, H.; Zhang, X.-J.; Xu, Z.-B.; Peng, L.; Wang, W.-L.; Wang, H.-B.; Chen, Z.; Hu, H.-Y. Enhancing Disinfection Performance of the Carbon Fiber-Based Flow-through Electrode System (FES) by Alternating Pulse Current (APC) with Low-Frequency Square Wave. Chemical Engineering Journal 2021, 410, 128399. https://doi.org/10.1016/j.cej.2020.128399.
(10) Yang, Z.; Ni, H.; Liu, P.; Liu, H.; Yang, K.; Zhang, Z.; Wang, B.; Li, X.; Chen, F. Nanofibrils in 3D Aligned Channel Arrays with Synergistic Effect of Ag/NPs for Rapid and Highly Efficient Electric Field Disinfection. Chinese Chemical Letters 2021, 32 (10), 3143-3148. https://doi.org/10.1016/j.cclet.2021.02.044.
(11) Pi, S.-Y.; Wang, Y.; Lu, Y.-W.; Liu, G.-L.; Wang, D.-L.; Wu, H.-M.; Chen, D.; Liu, H. Fabrication of Polypyrrole Nanowire Arrays-Modified Electrode for Point-of-Use Water Disinfection via Low-Voltage Electroporation. Water Research 2021, 207, 117825. https://doi.org/10.1016/j.watres.2021.117825.
(12) Cui, S.; Chen, S.; Wang, H.; Dong, L.; Wang, S. N-Doped Carbon-Coated Cu7S4 Nanowires on Cu Foam Supports for Water Disinfection. ACS Appl. Nano Mater. 2021, 4 (6), 6124-6134. https://doi.org/10.1021/acsanm.1c00930.
(13) Jun, S.; Chun, C.; Ho, K.; Li, Y. Design and Evaluation of a Millifluidic Insulator-Based Dielectrophoresis (DEP) Retention Device to Separate Bacteria from Tap Water. Water 2021, 13 (12), 1678. https://doi.org/10.3390/w13121678.
(14) Xie, L.; Shu, Y.; Hu, Y.; Cheng, J.; Chen, Y. SWNTs-PAN/TPU/PANI Composite Electrospun Nanofiber Membrane for Point-of-Use Efficient Electrochemical Disinfection: New Strategy of CNT Disinfection. Chemosphere 2020, 251, 126286. https://doi.org/10.1016/j.chemosphere. 2020.126286.
(15) Wang, S.; Wang, W.; Yue, L.; Cui, S.; Wang, H.; Wang, C.; Chen, S. Hierarchical Cu₂O Nanowires Covered by Silver Nanoparticles-Doped Carbon Layer Supported on Cu Foam for Rapid and Efficient Water Disinfection with Lower Voltage. Chemical Engineering Journal 2020, 382, 122855. https://doi.org/10.1016/j.cej.2019.122855.
(16) Zhou, J.; Yang, F.; Huang, Y.; Ding, W.; Xie, X. Smartphone-Powered Efficient Water Disinfection at the Point of Use. npj Clean Water 2020, 3 (1), 1-9. https://doi.org/10.1038/s41545-020-00089-9.
(17) Huo, Z.-Y.; Liu, H.; Wang, W.-L.; Wang, Y.-H.; Wu, Y.-H.; Xie, X.; Hu, H.-Y. Low-Voltage Alternating Current Powered Polydopamine-Protected Copper Phosphide Nanowire for Electroporation-Disinfection in Water. J. Mater. Chem. A 2019, 7 (13), 7347-7354. https://doi.org/10.1039/C8TA10942G.
(18) Huo, Z.-Y.; Liu, H.; Yu, C.; Wu, Y.-H.; Hu, H.-Y.; Xie, X. Elevating the Stability of Nanowire Electrodes by Thin Polydopamine Coating for Low-Voltage Electroporation-Disinfection of Pathogens in Water. Chemical Engineering Journal 2019, 369, 1005-1013. https://doi.org/10.1016/j.cej.2019.03.146.
(19) Thakur, A. K.; Singh, S. P.; Kleinberg, M. N.; Gupta, A.; Amusch, C. J. Laser-Induced Graphene-PVA Composites as Robust Electrically Conductive Water Treatment Membranes. ACS Appl. Mater. Interfaces 2019, 11 (11), 10914-10921. https://doi.org/10.1021/acsami.9b00510.
(20) Zhou, J.; Wang, T.; Chen, W.; Lin, B.; Xie, X. Emerging Investigator Series: Locally Enhanced Electric Field Treatment (LEEFT) with Nanowire-Modified Electrodes for Water Disinfection in Pipes. Environ. Sci.: Nano 2020, 7 (2), 397-403. https://doi.org/10.1039/C9EN00875F.
(21) Yue, L.; Chen, S.; Wang, S.; Wang, C.; Hao, X.; Cheng, Y. F. Water Disinfection Using Ag Nanoparticle-CuO Nanowire Co-Modified 3D Copper Foam Nanocomposites in High Flow under Low Voltages. Environ. Sci.: Nano 2019, 6 (9), 2801-2809. https://doi.org/10.1039/C9EN00455F.
(22) Zhou, J.; Wang, T.; Xie, X. Rationally Designed Tubular Coaxial-Electrode Copper Ionization Cells (CECICs) Harnessing Non-Uniform Electric Field for Efficient Water Disinfection. Environment International 2019, 128, 30-36. https://doi.org/10.1016/j.envint.2019.03.072.
(23) Pudasaini, S.; Perera, A. T. K.; Ahmed, S. S. U.; Chong, Y. B.; Ng, S. H.; Yang, C. An Electroporation Device with Microbead-Enhanced Electric Field for Bacterial Inactivation. Inventions 2020, 5 (1), 2. https://doi.org/10.3390/inventions5010002.
(24) Liu, H.; Ni, X.-Y.; Huo, Z.-Y.; Peng, L.; Li, G.-Q.; Wang, C.; Wu, Y.-H.; Hu, H.-Y. Carbon Fiber-Based Flow-Through Electrode System (FES) for Water Disinfection via Direct Oxidation Mechanism with a Sequential Reduction-Oxidation Process. Environ. Sci. Technol. 2019, 53 (6), 3238-3249. https://doi.org/10.1021/acs.est.8b07297.
(25) Thamaraiselvan, C.; Ronen, A.; Lerman, S.; Balaish, M.; Ein-Eli, Y.; Dosoretz, C. G. Low Voltage Electric Potential as a Driving Force to Hinder Biofouling in Self-Supporting Carbon Nanotube Membranes. Water Research 2018, 129, 143-153. https://doi.org/10.1016/j.watres.2017.11.004.
(26) Lin, L.; Meng, X.; Li, Q.; Huang, Z.; Wang, L.; Lin, K.; Chen, J.; Crittenden, J. Electrochemical Oxidation of Microcystis Aeruginosa Using a Ti/RuO2 Anode: Contributions of Electrochemically Generated Chlorines and Hydrogen Peroxide. Environ Sci Pollut Res 2018, 25 (28), 27924-27934. https://doi.org/10.1007/s11356-018-2830-4.
(27) Huo, Z.-Y.; Zhou, J.-F.; Wu, Y.; Wu, Y.-H.; Liu, H.; Liu, N.; Hu, H.-Y.; Xie, X. A Cu3P Nanowire Enabling High-Efficiency, Reliable, and Energy-Efficient Low-Voltage Electroporation-Inactivation of Pathogens in Water. J. Mater. Chem. A 2018, 6 (39), 18813-18820. https://doi.org/10.1039/C8TA06304D.
(28) Liang, S.; Lin, H.; Habteselassie, M.; Huang, Q. Electrochemical Inactivation of Bacteria with a Titanium Sub-Oxide Reactive Membrane. Water Research 2018, 145, 172-180. https://doi.org/10.1016/j.watres.2018.08.010.
(29) Wang, C.; Yue, L.; Wang, S.; Pu, Y.; Zhang, X.; Hao, X.; Wang, W.; Chen, S. Role of Electric Field and Reactive Oxygen Species in Enhancing Antibacterial Activity: A Case Study of 3D Cu Foam Electrode with Branched CuO—ZnO NWs. J. Phys. Chem. C 2018, 122 (46), 26454-26463. https://doi.org/10.1021/acs.jpcc.8b08232.
(30) Omi, F. R.; Choudhury, M. R.; Anwar, N.; Bakr, A. R.; Rahaman, Md. S. Highly Conductive Ultrafiltration Membrane via Vacuum Filtration Assisted Layer-by-Layer Deposition of Functionalized Carbon Nanotubes. Ind. Eng. Chem. Res. 2017, 56 (30), 8474-8484. https://doi.org/10.1021/acs.iecr.7b00847.
(31) Huo, Z.-Y.; Luo, Y.; Xie, X.; Feng, C.; Jiang, K.; Wang, J.; Hu, H.-Y. Carbon-Nanotube Sponges Enabling Highly Efficient and Reliable Cell Inactivation by Low-Voltage Electroporation. Environ. Sci.: Nano 2017, 4 (10), 2010-2017. https://doi.org/10.1039/C7EN00558J.
(32) Tian, J.; Feng, H.; Yan, L.; Yu, M.; Ouyang, H.; Li, H.; Jiang, W.; Jin, Y.; Zhu, G.; Li, Z.; Wang, Z. L. A Self-Powered Sterilization System with Both Instant and Sustainable Anti-Bacterial Ability. Nano Energy 2017, 36, 241-249. https://doi.org/10.1016/j.nanoen.2017.04.030.
(33) Wen, J.; Tan, X.; Hu, Y.; Guo, Q.; Hong, X. Filtration and Electrochemical Disinfection Performance of PAN/PANI/AgNWs-CC Composite Nanofiber Membrane. Environ. Sci. Technol. 2017, 51 (11), 6395-6403. https://doi.org/10.1021/acs.est.6b06290.
(34) Huo, Z.-Y.; Xie, X.; Yu, T.; Lu, Y.; Feng, C.; Hu, H.-Y. Nanowire-Modified Three-Dimensional Electrode Enabling Low-Voltage Electroporation for Water Disinfection. Environ. Sci. Technol. 2016, 50 (14), 7641-7649. https://doi.org/10.1021/acs.est.6b01050.
(35) Hong, X.; Wen, J.; Xiong, X.; Hu, Y. Silver Nanowire-Carbon Fiber Cloth Nanocomposites Synthesized by UV Curing Adhesive for Electrochemical Point-of-Use Water Disinfection. Chemosphere 2016, 154, 537-545. https://doi.org/10.1016/j.chemosphere.2016.04.013.
(36) Guo, L.; Ding, K.; Rockne, K.; Duran, M.; Chaplin, B. P. Bacteria Inactivation at a Sub-Stoichiometric Titanium Dioxide Reactive Electrochemical Membrane. Journal of Hazardous Materials 2016, 319, 137-146. https://doi.org/10.1016/j.jhazmat.2016.05.051.
(37) Mascia, M.; Monasterio, S.; Vacca, A.; Palmas, S. Electrochemical Treatment of Water Containing Microcystis Aeruginosa in a Fixed Bed Reactor with Three-Dimensional Conductive Diamond Anodes. Journal of Hazardous Materials 2016, 319, 111-120. https://doi.org/10.1016/j.jhazmat.2016.03.004.
(38) Zhu, A.; Liu, H. K.; Long, F.; Su, E.; Klibanov, A. M. Inactivation of Bacteria by Electric Current in the Presence of Carbon Nanotubes Embedded Within a Polymeric Membrane. Appl Biochem Biotechnol 2015, 175 (2), 666-676. https://doi.org/10.1007/s12010-014-1318-z.
(39) Racyte, J.; Bernard, S.; Paulitsch-Fuchs, A. H.; Yntema, D. R.; Bruning, H.; Rijnaarts, H. H. M. Alternating Electric Fields Combined with Activated Carbon for Disinfection of Gram Negative and Gram Positive Bacteria in Fluidized Bed Electrode System. Water Research 2013, 47 (16), 6395-6405. https://doi.org/10.1016/j.watres.2013.08.011.
(40) Liu, C.; Xie, X.; Zhao, W.; Liu, N.; Maraccini, P. A.; Sassoubre, L. M.; Boehm, A. B.; Cui, Y. Conducting Nanosponge Electroporation for Affordable and High-Efficiency Disinfection of Bacteria and Viruses in Water. Nano Lett. 2013, 13 (9), 4288-4293. https://doi.org/10.1021/n1402053z.
(41) Vecitis, C. D.; Schnoor, M. H.; Rahaman, Md. S.; Schiffman, J. D.; Elimelech, M. Electrochemical Multiwalled Carbon Nanotube Filter for Viral and Bacterial Removal and Inactivation. Environ. Sci. Technol. 2011, 45 (8), 3672-3679. https://doi.org/10.1021/es2000062.
(42) Schoen, D. T.; Schoen, A. P.; Hu, L.; Kim, H. S.; Heilshorn, S. C.; Cui, Y. High Speed Water Sterilization Using One-Dimensional Nanostructures. Nano Lett. 2010, 10 (9), 3628-3632. https://doi.org/10.1021/n1101944e.
(43) Feng, C.; Suzuki, K.; Zhao, S.; Sugiura, N.; Shimada, S.; Maekawa, T. Water Disinfection by Electrochemical Treatment. Bioresource Technology 2004, 94 (1), 21-25. https://doi.org/10.1016/j.biortech.2003.11.021.
(44) Sale, A. J. H.; Hamilton, W. A. Effects of High Electric Fields on Microorganisms: I. Killing of Bacteria and Yeasts. Biochimica et Biophysica Acta (BBA)—General Subjects 1967, 148 (3), 781-788. https://doi.org/10.1016/0304-4165(67)90052-9.
(45) Uemura, K.; Isobe, S. Developing a New Apparatus for Inactivating Escherichia Coli in Saline Water with High Electric Field AC. Journal of Food Engineering 2002, 53 (3), 203-207. https://doi.org/10.1016/S0260-8774(01)00158-3.
(46) Liang, Z.; Fan, D. (Emma). Versatile Microparticle Propulsion System by Light-Guided Dielectrophoresis: Proposed Method and Theoretical Calculation. Journal of Applied Physics 2021, 130 (5), 054902. https://doi.org/10.1063/5.0052117.
(47) Huang, E.; White, T.; Wang, B.; Shi, H.; Liu, J. Disinfection of Escherichia Coli by a Reactive Electrochemical Membrane System Involving Activated Carbon Fiber Cloth (ACFC). Water 2019, 11 (3), 430. https://doi.org/10.3390/w11030430.
(48) Wang, Y.; Li, A.; Cui, C. Remediation of Heavy Metal-Contaminated Soils by Electrokinetic Technology: Mechanisms and Applicability. Chemosphere 2021, 265, 129071. https://doi.org/10.1016/j.chemosphere.2020.129071.
(49) Rajendran, S.; Priya, T. A. K.; Khoo, K. S.; Hoang, T. K. A.; Ng, H.-S.; Munawaroh, H. S. H.; Karaman, C.; Orooji, Y.; Show, P. L. A Critical Review on Various Remediation Approaches for Heavy Metal Contaminants Removal from Contaminated Soils. Chemosphere 2022, 287, 132369. https://doi.org/10.1016/j.chemosphere.2021.132369.
(50) Acar, Y. B.; Gale, R. J.; Alshawabkeh, A. N.; Marks, R. E.; Puppala, S.; Bricka, M.; Parker, R. Electrokinetic Remediation: Basics and Technology Status. Journal of Hazardous Materials 1995, 40 (2), 117-137. https://doi.org/10.1016/0304-3894(94)00066-P.
(51) Martínez-Huitle, C. A.; Panizza, M. Electrochemical Oxidation of Organic Pollutants for Wastewater Treatment. Current Opinion in Electrochemistry 2018, 11, 62-71. https://doi.org/10.1016/j.coelec.2018.07.010.
(52) Moya, A. A. Identification of Characteristic Time Constants in the Initial Dynamic Response of Electric Double Layer Capacitors from High-Frequency Electrochemical Impedance. Journal of Power Sources 2018, 397, 124-133. https://doi.org/10.1016/j.jpowsour.2018.07.015.
(53) Berner, E. K. Global Environment: Water, Air, and Geochemical Cycles/Elizabeth Kay Berner, Robert A. Berner., 2nd ed.; Princeton University Press: Princeton, N.J, 2012.
(54) Morgan, H.; Green, N.; Ramos, A. Nano-Scale AC Electrokinetics and Electrohydrodynamics. J. Phys. D. Appl. Phys. 2016, 50 (1), 011001. https://doi.org/10.1088/1361-6463/50/1/011001.

### Example Implementations

Clause 1. A method for removing bacteria from a water sample, the method comprising
introducing water comprising a population of bacteria into a purification chamber, wherein the purification chamber comprises a plurality of electrodes;
generating an AC electric field within the purification chamber for a period of time effective to induce migration and capture of at least a portion of the bacteria on the plurality of electrodes; and
removing the water from the purification chamber;
wherein each of the plurality of electrodes comprises a porous dendritic graphite foam.
   Clause 2. The method of Clause 1, wherein the plurality of electrodes are arranged in a substantially parallel orientation.
   Clause 3. The method of Clause 2, wherein the plurality of electrodes are separated by an inter-electrode distance of from 25 microns to 1000 microns, such as from 50 microns to 500 microns.
   Clause 4. The method of any one of Clauses 1-3, wherein the plurality of electrodes comprise from four to one hundred electrodes.
   Clause 5. The method of any one of Clauses 1-4, wherein the generating an AC electric field comprises applying a voltage of from greater than 0 V to 20 V, such as from 2 V to 20 V.
   Clause 6. The method of any one of Clauses 1-5, AC electric field has a frequency of from 1 Hz to 80 MHz, such as from 1 MHz to 20 MHz.
   Clause 7. The method of any one of Clauses 1-6, wherein generating an AC electric field comprises generating the AC electric field for at least 1 minute, such as generating the AC electric field for from 5 minutes to 30 minutes.
   Clause 8. The method of any one of Clauses 1-7, wherein the porous dendritic graphite foams comprise porous graphite struts deposed on the surfaces of a core.
   Clause 9. The method of Clause 8, wherein the struts comprise porous dendrites.
   Clause 10. The method of any of Clauses 8-9, wherein each strut has a single point of attachment to the core.
   Clause 11. The method of any one of Clauses 1-10, wherein the porous dendritic graphite foams have a thickness of at least 100 μm, at least 200 μm, at least 300 μm, at least 400 μm, at least 500 μm, at least 600 μm, at least 700 μm, at least 800 μm, at least 900 μm, or at least 1,000 μm.
   Clause 12. The method of any one of Clauses 9-11, wherein the porous dendrites have an average pore size from 1-10,000 nm, 1-5,000 nm, 1-2,500 nm, 1-2,000 nm, 1-1,500 nm, 1-1,000 nm, 10-1,000 nm, 100-1,000 nm, 100-500 nm, 500-1,000 nm, or 500-2,000 nm.
   Clause 13. The method of any of Clauses 8-12, wherein the core comprises an electrically conductive core.
   Clause 14. The method of any one of Clauses 8-13, wherein the core comprises a solid core.
   Clause 15. The method of Clause 14, wherein the solid core comprises carbon cloth, carbon paper, silicon, an electrically conducting oxide such as indium tin oxide, fluorine doped tin oxide, niobium doped anatase, or doped zinc oxide.
   Clause 16. The method of any one of Clauses 8-13, wherein the core comprises a porous core.
   Clause 17. The method of Clause 16, wherein the porous core comprises porous graphite.
   Clause 18. The method of Clause 16 or 17, wherein the porous core has an average pore size from 1-1,000 μm, 10-1,000 μm, 10-500 μm, 50-500 μm, or 100-500 μm.
   Clause 19. The method of any one of Clauses 16-18, wherein the core comprises a multi-layered porous core.
   Clause 20. The method of Clause 19, wherein the multi-layered porous core comprises an interior portion and shell portion.
   Clause 21. The method of Clause 20, wherein the shell portion comprises pores having an average pore size that is no more than 50%, 40%, 30%, 20%, 10%, 5%, or 1% the average pore size of the interior portion.
   Clause 22. The method of any one of Clauses 20-21, wherein the interior portion has an average pore size from 10-1,000 μm, 25-1,000 μm, 50-1,000 μm, 50-500 μm, 100-500 μm.
   Clause 23. The method of any one of Clauses 20-22, wherein the shell portion has an average pore size from 1-100 μm, 1-50 μm, 1-25 μm, 2-25 μm, 2-15 μm, 2-10 μm, 2-8 μm, 2-5 μm, 5-25 μm, 5-15 μm, 5-10 μm or 5-8 μm.
   Clause 24. The method of any one of Clauses 1-23, wherein the porous dendritic graphite foams have a BET surface area of at least 5.0 m²/g, at least 5.5 m²/g, at least 6.0 m²/g, at least 6.5 m²/g, at least 7.0 m²/g, at least 7.5 m²/g, at least 8.0 m²/g, at least 8.5 m²/g, at least 9.0 m²/g, at least 9.5 m²/g, or at least 10.0 m²/g.
   Clause 25. The method of any one of Clauses 1-24, wherein the porous dendritic graphite foams have an areal density of at least 0.01 mg/cm², at least 0.05 mg/cm², at least 0.10 mg/cm², at least 0.15 mg/cm², at least 0.20 mg/cm², at least 0.25 mg/cm², at least 0.30 mg/cm², at least 0.35 mg/cm², at least 0.40 mg/cm², at least 0.45 mg/cm², or at least 0.50 mg/cm².
   Clause 26. The method of any one of Clauses 1-25, wherein the porous dendritic graphite foams has a volumetric surface area of at least 0.01 m²/cm³, at least 0.05 m²/cm³, at least 0.10 m²/cm³, at least 0.15 m²/cm³, at least 0.20 m²/cm³, at least 0.25 m²/cm³, at least 0.30 m²/cm³, at least 0.35 m²/cm³, at least 0.40 m²/cm³, at least 0.45 m²/cm³, at least 0.50 m²/cm³, at least 0.55 m²/cm³, at least 0.60 m²/cm³, at least 0.65 m²/cm³, at least 0.70 m²/cm³, at least 0.75 m²/cm³, at least 0.80 m²/cm³, at least 0.85 m²/cm³, at least 0.90 m²/cm³, at least 0.95 m²/cm³, or at least 1.0 m²/cm³.
   Clause 27. The method of any of Clauses 1-26, wherein the porous dendritic graphite foams are made by a method that comprises:
(a) placing a conductive substrate in an electrolyte solution, wherein the electrolyte solution is in electrical communication with an electrode;
(b) applying an electric current via the electrode sufficient to grow metal dendrites on the surface of the conductive substrate;
(c) annealing the metal dendrites and conductive substrate;
(d) depositing carbon upon the annealed metal dendrites and the conductive substrate; and
(e) removing the annealed metal dendrites and conductive substrate to obtain a three-dimensional graphite foam comprising porous graphite dendrites radiating from a porous core.
   Clause 28. The method of Clause 27, wherein the conductive substrate comprises a conductive metal, silicon, or a conductive polymer.
   Clause 29. The method of Clause 27 or 28, wherein the conductive substrate comprises a solid substrate.
   Clause 30. The method of Clause 27 or 28, wherein the conductive substrate comprises a porous substrate.
   Clause 31. The method of Clause 30, wherein the porous substrate comprises a metal foam.
   Clause 32. The method of Clause 31, wherein the metal foam comprises a nickel foam, a copper foam, an iron foam, a zinc foam, an aluminum foam, or a tin foam.
   Clause 33. The method of any one of Clauses 27-32, wherein the electrolyte solution comprises a copper salt, a nickel salt, a cobalt salt, or a mixture thereof.
   Clause 34. The method of any one of Clauses 27-33, wherein the applied electric current is at least −25 mA.
   Clause 35. The method of any one of Clauses 27-34, wherein the electric current is applied at an applied voltage from −2.5 V-2.5 V.
   Clause 36. The method of any one of Clauses 27-35, wherein the electric current is applied to the conductive substrate from 25-500 C/in², relative to the surface area of the conductive substrate.
   Clause 37. The method of any one of Clauses 27-36, wherein step (b) comprises:
(b1) applying an electric current via the electrode sufficient to grow metal dendrites on the surface of the conductive substrate;
(b2) rotating the metal substrate relative to the electrode; and
(b3) applying an electric current via the electrode sufficient to grow metal dendrites on the surface of the rotated conductive substrate.
   Clause 38. The method of Clause 37, comprising multiple rotation-dendrite growth sequences.
   Clause 39. The method of any one of Clauses 27-38, wherein the depositing step comprises chemical vapor deposition or hydrothermal synthesis using a carbon source, or thermal annealing of a carbon source coated on the surface.
   Clause 40. The method of Clause 39, wherein the carbon source comprises a C₂₋₄ hydrocarbon or a carbon-backboned polymer.
   Clause 41. The method of any one of Clauses 27-40, wherein the depositing step is conducted at a temperature less than about 1,000° C.
   Clause 42. The method of Clause 40, wherein the depositing step is conducted at a temperature between about 100-1,000° C.
   Clause 43. The method of any of Clauses 27-42, wherein the conductive substrate is removed by chemical etching.
   Clause 44. The method of Clause 43, wherein the chemical etching comprises treatment with at least one acid.
   Clause 45. The method of Clause 43, wherein the chemical etching comprises a treatment with a mineral acid and a Lewis acid.
   Clause 46. The method of Clause 45, wherein the mineral acid comprises HCl, HBr, HI, HF, HNO₃, H₂SO₄, H₃PO₄, or a mixture thereof.
   Clause 47. The method of Clause 45, wherein the Lewis acid comprises a transition metal salt.
   Clause 48. The method of any of Clauses 1-47, wherein the method removes at least 70%, at least 75%, at least 80%, at least 85%, at least 90%, at least 95%, at least 98%, at least 99%, or at least 99.9% of the population of bacteria present in the water sample

The compositions, systems, and methods of the appended claims are not limited in scope by the specific compositions, systems, and methods described herein, which are intended as illustrations of a few aspects of the claims. Any compositions, systems, and methods that are functionally equivalent are intended to fall within the scope of the claims. Various modifications of the compositions, systems, and methods in addition to those shown and described herein are intended to fall within the scope of the appended claims. Further, while only certain representative compounds, components, compositions, and method steps disclosed herein are specifically described, other combinations of the compounds, components, compositions, and method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

The term “comprising” and variations thereof as used herein is used synonymously with the term “including” and variations thereof and are open, non-limiting terms. Although the terms “comprising” and “including” have been used herein to describe various embodiments, the terms “consisting essentially of” and “consisting of” can be used in place of “comprising” and “including” to provide for more specific embodiments of the invention and are also disclosed. Other than where noted, all numbers expressing geometries, dimensions, and so forth used in the specification and claims are to be understood at the very least, and not as an attempt to limit the application of the doctrine of equivalents to the scope of the claims, to be construed in light of the number of significant digits and ordinary rounding approaches.

Unless defined otherwise, all technical and scientific terms used herein have the same meanings as commonly understood by one of skill in the art to which the disclosed invention belongs. Publications cited herein and the materials for which they are cited are specifically incorporated by reference.

What is claimed is:

1. A method for removing bacteria from a water sample, the method comprising
introducing water comprising a population of bacteria into a purification chamber, wherein the purification chamber comprises a plurality of electrodes;
generating an AC electric field within the purification chamber for a period of time effective to induce migration and capture of at least a portion of the bacteria on the plurality of electrodes; and
removing the water from the purification chamber;
wherein each of the plurality of electrodes comprises a porous dendritic graphite foam.

2. The method of claim 1, wherein the plurality of electrodes are arranged in a substantially parallel orientation.

3. The method of claim 2, wherein the plurality of electrodes are separated by an inter-electrode distance of from 25 microns to 1000 microns.

4. The method of claim 1, wherein the plurality of electrodes comprise from four to one hundred electrodes.

5. The method of claim 1, wherein the generating an AC electric field comprises applying a voltage of from greater than 0 V to 20 V.

6. The method of claim 1, AC electric field has a frequency of from 1 Hz to 80 MHz.

7. The method of claim 1, wherein generating an AC electric field comprises generating the AC electric field for from 5 minutes to 30 minutes.

8. The method of claim 1, wherein the porous dendritic graphite foams comprise porous graphite struts deposed on a surface of a core.

9. The method of claim 8, wherein the struts comprise porous dendrites.

10. The method of claim 1, wherein the porous dendritic graphite foams have a thickness of at least 100 μm.

11. The method of claim 1, wherein the porous dendritic graphite foams have an average pore size from 1-10,000 nm.

12. The method of claim 1, wherein the porous dendritic graphite foams have a BET surface area of at least 5.0 m²/g.

13. The method of claim 1, wherein the porous dendritic graphite foams have an areal density of at least 0.01 mg/cm².

14. The method of claim 1, wherein the porous dendritic graphite foams have a volumetric surface area of at least 0.01 m²/cm³.

15. The method of claim 1, wherein the porous dendritic graphite foams are made by a method that comprises:
(a) placing a conductive substrate in an electrolyte solution, wherein the electrolyte solution is in electrical communication with an electrode;
(b) applying an electric current via the electrode sufficient to grow metal dendrites on the surface of the conductive substrate;
(c) annealing the metal dendrites and conductive substrate;
(d) depositing carbon upon the annealed metal dendrites and the conductive substrate; and
(e) removing the annealed metal dendrites and conductive substrate to obtain a three-dimensional graphite foam comprising porous graphite dendrites radiating from a porous core.

16. The method of claim 15, wherein the electric current is applied to the conductive substrate from 25-500 C/in², relative to the surface area of the conductive substrate.

17. The method of claim 15, wherein step (b) comprises:
(b1) applying an electric current via the electrode sufficient to grow metal dendrites on the surface of the conductive substrate;
(b2) rotating the metal substrate relative to the electrode; and
(b3) applying an electric current via the electrode sufficient to grow metal dendrites on the surface of the rotated conductive substrate.

18. The method of claim 17, wherein the depositing step comprises chemical vapor deposition or hydrothermal synthesis using a carbon source, or thermal annealing of a carbon source coated on the surface.

19. The method of claim 18, wherein the carbon source comprises a C₂₋₄ hydrocarbon or a carbon-backboned polymer.

20. The method of claim 15, wherein the conductive substrate is removed by chemical etching.
